(19) United States
(12) Patent Application Publication
(10) Pub. No.: US 2009/0015765 A1
(43) Pub. Date: Jan. 15, 2009

(54) INK FOR USE IN A COLOR FILTER, COLOR FILTER, METHOD OF MANUFACTURING A COLOR FILTER, IMAGE DISPLAY APPARATUS, ELECTRONIC APPARATUS

(75) Inventors: Hiroshi TAKIGUCHI, Suwa (JP); Masaya SHIBATANI, Matsumoto (JP); Mitsuhiro ISOBE, Kofu (JP); Hiroshi KIGUCHI, Suwa (JP); Hidekazu MORIYAMA, Fujimi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/171,547

(22) Filed: Jul. 11, 2008

(30) Foreign Application Priority Data
Jul. 12, 2007 (JP) 2007-182890

(51) Int. Cl. G02F 1/1335; C09D 11/00; G03F 1/00

(52) U.S. Cl. 349/106; 106/31.13; 430/7

(57) ABSTRACT

An ink for use in manufacturing a color filter by an ink-jet together with other inks, the ink having a predetermined color which is different from colors of the other inks. The ink comprises a coloring agent which has a color corresponding to the predetermined color of the ink, and a liquid medium in which the coloring agent is dissolved and/or dispersed, the liquid medium comprised of a component A and a component B, wherein a boiling point of the component B is higher than a boiling point of the component A, and a viscosity of the component B at a temperature of 25° C. is higher than a viscosity of the component A at a temperature of 25° C. The ink can be used for manufacturing the color filter which has no uneven color or no uneven density. Further, the ink can also be used for manufacturing the color filter which has excellent uniformity of characteristics among the manufactured color filters. A color filter which has no uneven color or no uneven density and has excellent uniformity of characteristics among the manufactured color filters is also provided. A method of manufacturing such a color filter is also provided. An image display apparatus that can suitably use such a color filter is also provided. An electronic apparatus that can suitably use such an image display apparatus is also provided.

### BACKGROUND

1. Technical Field

The present invention relates to an ink for use in a color filter, a color filter, a method of manufacturing a color filter, an image display apparatus and an electronic apparatus, and more specifically relates to an ink for use in a color filter, a color filter manufactured using the ink, a method of manufacturing the color filter, an image display apparatus provided with the color filter and an electronic apparatus provided with the image display apparatus.

2. Related Art

Generally, a color filter is used in a liquid crystal display apparatus (LCD) which can display an image composed of different colors.

A conventional color filter has been manufactured using a so called “photolithography method”. The photolithography method is carried out by the following steps. First, a material containing a coloring agent, a photosensitive resin, a functionalized monomer, a polymerization initiator and the like is prepared (composition for forming a coloring layer). Next, a coating film constituted of the composition is formed on a substrate. Thereafter, the coating film is subjected to a photosensitive treatment in which light is irradiated to the coating film through a photo mask. Then, the coating film is subjected to a development treatment to obtain the color filter.

In more detail, in such a method, the color filter is manufactured according to the following steps, for example. First, a first coating film consisted of the composition for a first color (e.g. Red) is formed on substantially the entire surface of a substrate. Thereafter, parts of the first coating film which will be used as first coloring parts of the first color are cured, and then the remaining portion of the first coating film other than the cured parts thereof is removed.

Next, a second coating film consisted of the composition for a second color which is different from the first color (e.g. Blue) is formed on substantially the entire surface of the substrate in a state that the cured parts of the first color have been formed on the substrate. Thereafter, parts of the second coating film which will be used as second coloring parts of the second color are cured so that the second coloring parts do not overlap with the cured parts of the first color, and then the remaining portion of the second coating film other than the cured parts thereof is removed.

Next, a third coating film consisted of the composition for a third color which is different from the first and second colors (e.g. Green) is formed on substantially the entire surface of the substrate in a state that the cured parts of the first and second colors have been formed on the substrate. Thereafter, parts of the third coating film which will be used as third coloring parts of the third color are cured so that the cured parts do not overlap with the cured parts of the first and second colors, and then the remaining portion of the third coating film other than the cured parts thereof is removed. Through these steps, the color filter is manufactured.

Therefore, in the conventional method of manufacturing the color filter described above, only a part of the coating film of each color is used as the coloring parts in the obtained color filter and most of the coating film other than the coloring parts thereof is removed in the finally obtained color filter. That is, only a small part of each coating film is used for forming the color filter. This results in an increased cost for manufacturing the color filter. Further, such a method is not preferable in view of a resource saving.

Recently, another method for manufacturing a color filter is proposed (one example of such a method is disclosed in JP-A 2002-372613). In this method, a coloring layer corresponding to each color of a color filter is formed by using an ink-jet (droplet discharge head). In such a method of manufacturing the color filter using the ink-jet, partitioning walls (banks) are formed on a substrate for preventing inks of the respective colors from mixing to each other as disclosed in the JP-A 2002-372613. Then, the inks of the respective colors are discharged into predetermined spaces defined by the partitioning walls on the substrate. Thereafter, the discharged inks are dried, thereby forming coloring layers in coloring parts of the respective colors.

In such a method, it is easy to control discharge positions of droplets of a material for forming the coloring layer of each color (that is, an ink for forming a coloring layer). It is also possible to reduce a waste of the material for forming the coloring layer of each color. Therefore, it is possible to reduce adverse effects on the environment and decrease a cost for manufacturing the color filter.

However, in the method of manufacturing the color filter disclosed in the JP-A 2002-372613, there is a problem in that variation of a thickness of the formed coloring parts is likely to occur. When such a problem occurs, uneven color or uneven density generates at various portions of the coloring parts of respective colors. As a result, the uneven color or the uneven density also generates at various portions in a manufactured color filter corresponding to such coloring parts of the color filter.

Further, variation of characteristics of the color filter, in particular variation in color properties such as color reproducible range (gamut of reproducible colors), occurs among a large number of color filters manufactured using such a method. Therefore, reliability of the manufactured color filter lowers. In particular, when a color filter for use in a large size liquid crystal display apparatus is manufactured, such a problem becomes conspicuous.

### SUMMARY

Accordingly, it is a first object of the present invention to provide an ink for use in a color filter manufactured by an ink-jet. The ink can be used for manufacturing a color filter which has no uneven color or no uneven density in coloring parts thereof and has excellent uniformity of characteristics among the manufactured color filters.

Further, it is also a second object of the present invention to provide a color filter which has no uneven color or no uneven density and has excellent uniformity of characteristics among the manufactured color filters.

Furthermore, it is also a third object of the present invention to provide a method of manufacturing such a color filter.

Furthermore, it is also a fourth object of the present invention to provide an image display apparatus provided with such a color filter.

Furthermore, it is also a fifth object of the present invention to provide an electronic apparatus provided with such an image display apparatus.

These objects are achieved by the present invention described below.

In a first aspect of the present invention, there is provided an ink for use in manufacturing a color filter by an ink-jet together with other inks, the ink having a predetermined color which is different from colors of the other inks, the ink comprising a coloring agent which has a color corresponding to the predetermined color of the ink, and a liquid medium in which the coloring agent is dissolved and/or dispersed, the liquid medium comprised of a component A and a component B, wherein a boiling point of the component B is higher than a boiling point of the component A, and a viscosity of the component B at a temperature of 25° C. is higher than a viscosity of the component A at a temperature of 25° C.

By using the ink described above, it is possible to reliably manufacture a color filter of which coloring parts have no uneven color or no uneven density. Therefore, when a number of color filters are manufactured using the ink, they can have excellent uniformity in their characteristics.

In the ink according to the present invention, it is preferred that when the boiling point of the component A under an atmospheric pressure is defined as T_{bp}(a) [° C.] and the boiling point of the component B under the atmospheric pressure is defined as T_{bp}(b) [° C.], T_{bp}(a) and T_{bp}(b) satisfy a relation: 20≦T_{bp}(b)−T_{bp}(a)≦70.

By using the ink described above, since a thickness of the coloring parts of the manufactured color filter becomes even, it is possible to reliably prevent uneven color or uneven density from generating in the coloring parts thereof. Therefore, the manufactured color filters can have more excellent uniformity in their characteristics.

In the ink according to the present invention, it is also preferred that when the viscosity of the component A at a temperature of 25° C. is defined as η(a) [mPa·s] and the viscosity of the component B at a temperature of 25° C. is defined as η(b) [mPa·s], η(a) and η(b) satisfy a relation: 1≦η(b)−η(a)≦15.

By using the ink described above, since a thickness of the coloring parts of the manufactured color filter becomes even, it is possible to reliably prevent uneven color or uneven density from generating in the coloring parts thereof. Therefore, the manufactured color filters can have more excellent uniformity in their characteristics.

In the ink according to the present invention, it is also preferred that when an amount of the component A in the ink is defined as X [wt %] and an amount of the component B in the ink is defined as Y [wt %], X and Y satisfy a relation: 1.0≦X/Y≦20.

By using the ink described above, since a thickness of the coloring parts of the manufactured color filter becomes even, it is possible to reliably prevent uneven color or uneven density from generating in the coloring parts thereof. Therefore, the manufactured color filters can have more excellent uniformity in their characteristics.

In the ink according to the present invention, it is also preferred that the other inks contain the liquid medium, and the liquid medium contained in each of the ink and the other inks includes as the component A any one or more selected from the group comprising diethylene glycol dimethyl ether, diacetone alcohol, 3-methoxy n-butyl acetate, dipropylene glycol dimethyl ether, 3-ethoxy ethyl propionate, diethylene glycol ethyl methyl ether, diethylene glycol diethyl ether, ethyl octanoate, ethylene glycol monobutyl ether acetate, ethylene glycol monobutyl ether, cyclohexyl acetate, 1,3-butylene glycol diacetate, ethylene glycol butyl methyl ether, ethylene glycol hexyl methyl ether, ethylene glycol dibutyl ether, and 2-(2-methoxy-1-methylethoxy)-1-methyl ethyl acetate.

By using the ink described above, the thickness of the coloring parts of the manufactured color filter becomes even. Further, it is also possible to reliably discharge a stable amount of the ink from nozzles of a droplet discharge head. As a result, it is possible to efficiently prevent uneven color or uneven density from generating in the coloring parts of the manufactured color filter. Therefore, the manufactured color filters can have more excellent uniformity in their characteristics.

In the ink according to the present invention, it is also preferred that the other inks contain the liquid medium, and the liquid medium contained in each of the ink and the other inks includes as the component B any one or more selected from the group comprising tripropylene glycol methyl ether, triethylene glycol monomethyl ether, 4-methyl-1,3-dioxolane-2-on, diethylene glycol monobutyl ether, diethylene glycol monobutyl ether acetate, bis(2-buthoxyethyl)ether, 1,3-butylene glycol diacetate, triethylene glycol diacetate, ethylene glycol monobutyl ether acetate, triethylene glycol butyl methyl ether, nonyl alcohol, triacetine, propylene glycol phenyl ether, and diethylene glycol monohexyl ether.

By using the ink described above, the thickness of the coloring parts of the manufactured color filter becomes even. Further, it is also possible to reliably discharge a stable amount of the ink from nozzles of a droplet discharge head. As a result, it is possible to efficiently prevent uneven color or uneven density from generating in the coloring parts of the manufactured color filter. Therefore, the manufactured color filters can have more excellent uniformity in their characteristics.

In the ink according to the present invention, it is also preferred that a viscosity of the ink at the temperature of 25° C. is in the range of 5 to 12 mPa·s.

By using the ink described above, it is possible to efficiently prevent uneven color or uneven density from generating in the coloring parts of the manufactured color filter. Therefore, the manufactured color filters can have more excellent uniformity in their characteristics. Further, it is also possible to efficiently prevent nozzle clogging from occurring in the droplet discharge head for discharging the ink. As a result, the productivity of the color filter can be made excellent.

In the ink according to the present invention, it is also preferred that the predetermined color of the ink includes a red color, a green color and a blue color.

According to the ink described above, it is possible to display a color image composed of such three colors reliably.

In a second aspect of the present invention, there is provided a color filter manufactured using the ink described above.

According to the color filter described above, it is possible to prevent uneven color or uneven density from generating in the coloring parts thereof. Therefore, the manufactured color filters can have more excellent uniformity in their characteristics.

In a third aspect of the present invention, there is provided a method of manufacturing a color filter, the method comprising preparing a substrate having a large number of cells to which a plurality of inks having different colors are to be discharged, discharging the plurality of inks into the cells by an ink-jet, and drying the plurality of inks which are discharged into the cells by the ink-jet, wherein each of the plurality of inks comprises a coloring agent which has a predetermined color corresponding to the color of one ink in the plurality of inks and a liquid medium in which the coloring agent is dissolved and/or dispersed, and the liquid medium comprised of a component A and a component B, wherein a boiling point of the component B is higher than a boiling point of the component A, and a viscosity of the component B at a temperature of 25° C. is higher than a viscosity of the component A at a temperature of 25° C.

According to the method described above, it is possible to prevent uneven color or uneven density from generating in the coloring parts thereof. Therefore, the manufactured color filters can have more excellent uniformity in their characteristics.

In a fourth aspect of the present invention, there is provided an image display apparatus provided with the color filter described above.

According to the image display apparatus described above, it is possible to prevent uneven color or uneven density from generating in the coloring parts of the color filter of the image display apparatus. Therefore, the manufactured image display apparatuses can have more excellent uniformity in their characteristics.

In the image display apparatus according to the present invention, it is preferred that the image display apparatus is a liquid crystal panel.

According to the image display apparatus described above, it is possible to prevent uneven color or uneven density from generating in the coloring parts of the color filter of the image display apparatus. Therefore, the manufactured image display apparatuses can have more excellent uniformity in their characteristics.

In a fifth aspect of the present invention, there is provided an electronic apparatus provided with the image display apparatus described above.

According to the image display apparatus described above, it is possible to prevent uneven color or uneven density from generating in the coloring parts of the color filter of the image display apparatus. Therefore, the manufactured image display apparatuses can have more excellent uniformity in their characteristics.

### BRIEF DESCRIPTION OF THE DRAWINGS

FIG. 1 is a cross sectional view which shows a preferred embodiment of a color filter according to the present invention.

FIG. 2 is a cross sectional view which shows a manufacturing method of the color filter.

FIG. 3 is a perspective view which shows a droplet discharge apparatus used in manufacturing the color filter.

FIG. 4 is an illustration of a droplet discharge means of the droplet discharge apparatus shown in FIG. 3, which is viewed from the side of a stage of the apparatus.

FIG. 5 is a bottom view of a droplet discharge head of the droplet discharge apparatus shown in FIG. 3.

FIG. 6(a) is a perspective view of the droplet discharge head of the droplet discharge apparatus shown in FIG. 3, in which a part of the head is removed, and FIG. 6(b) is a cross sectional view of the droplet discharge head of the droplet discharge apparatus.

FIG. 7 is a cross sectional view which shows an embodiment of the liquid crystal display apparatus of the present invention.

FIG. 8 is a perspective view of a personal computer of a mobile type (or a notebook type) which is one example of the electronic apparatus of the present invention.

FIG. 9 is a perspective view which shows the structure of a mobile phone (including the personal handyphone system (PHS)) which is another example of the electronic apparatus according to the present invention.

FIG. 10 is a perspective view which shows the structure of a digital still camera which is yet another example of the electronic apparatus according to the present invention.

### DESCRIPTION OF EXEMPLARY EMBODIMENTS

Hereinbelow, with reference to the accompanying drawings, preferred embodiments of an ink for use in a color filter, a color filter, a method for manufacturing such a color filter, an image display apparatus and an electric apparatus according to the present invention will be described in details.

An Ink for Use in Color Filter

An ink 2 for use in a color filter 1 (hereinafter, simply referred to as “ink”) according to the present invention is an ink which is used for manufacturing a color filter 1 (forming coloring parts 12 of the color filter 1). In particular, the ink 2 according to the present invention is an ink which is used for manufacturing the color filter 1 by an ink-jet.

In this regard, it is to be noted that drying of the ink 2 means that a liquid component (organic type liquid, water and the like) contained in the ink 2 is evaporated (vaporized) or removed in this specification.

The ink 2 according to the present invention contains a coloring agent having a predetermined color, a liquid medium in which the coloring agent is dissolved and/or dispersed, and a resin material.

In the meantime, recently, a color filter is manufactured by using an ink-jet. The color filter is manufactured by the steps of discharging (ejecting) inks having different colors on a substrate, and drying the discharged (ejected) inks to thereby form coloring parts corresponding to each color.

Such a method can reduce a waste of a material for forming the coloring parts (an ink for forming coloring parts) as compared to a photolithography method which is widely used heretofore. Therefore, it is possible to reduce adverse effects on an environment. Further, it is also possible to decrease a cost for manufacturing the color filter. Furthermore, a method of manufacturing the color filter by the ink-jet also has an advantage in that it is easy to control discharge (ejection) positions of droplets of inks for forming the coloring parts (an ink for forming coloring parts).

However, in the conventional method of manufacturing the color filter using the ink-jet, there is a problem in that variation of a thickness of the formed coloring parts is likely to occur.

Such a problem is caused by the following two reasons. When inks discharged on a substrate are dried, a liquid component contained in the inks is evaporated. At this time, convective flow is caused in the inks. On the other hand, bubbles generate from the inks in the middle of drying process depending on dry conditions and a kind of liquid component contained in the inks.

In particular, the convective flow materially affects generation of uneven density. Further, since a bank for the coloring parts is previously subjected to a liquid repelling treatment for carrying out the ink-jet, drying speed becomes fast at the vicinity of edges of the bank. Therefore, both temperature difference in the discharged ink and uneven surface tension thereof cause the convective flow, and as a result thereof variation of the thickness of the coloring parts occurs.

When such a problem occurs, uneven color or uneven density generates at various portions of the coloring parts of respective colors. As a result, the uneven color or the uneven density also generates at various portions of the manufactured color filter.

Further, variation of characteristics of the color filter, in particular variation in color properties such as color reproducible range (gamut of reproducible colors), occurs among a large number of color filters manufactured using such a method. Therefore, reliability of the manufactured color filter lowers. This occurs in the following cases conspicuously. One is a case that a color filter for a relatively large size display (the diagonal size thereof is 80 cm or larger) is manufactured. The other is a case that a number of color filters are manufactured continuously.

As a result, the present inventors focused their attention on a drying state of the discharged inks with the lapse of time. And the present inventors conceived that changes of a viscosity of the ink during the drying process affects variation of the thickness of the coloring parts to be formed. The present inventors devoted themselves to study this conception further. As a result, the present inventors have accomplished the present invention.

In the present invention, a liquid medium contained in the ink 2 is constituted of a component A and a component B. A boiling point of the component B under an atmospheric pressure is higher than a boiling point of the component A under the atmospheric pressure. A viscosity of the component B at a temperature of 25° C. is higher than a viscosity of the component A at a temperature of 25° C. Inclusion of the compounds A and B in the liquid medium makes it possible to solve occurrence of the problems as described above reliably.

The ink 2 containing the liquid medium constituted of such a component A and component B can exhibit superior discharge characteristics of droplets due to the inclusion of the component A in the liquid medium. As a result, it is possible to equalize an discharged amount of the ink 2 from nozzles 118 of a droplet discharge head 114.

Further, during manufacturing a color filter 1 it is possible to make the surfaces of the ink 2 discharged into the cells 14 flat reliably. When the ink 2 discharged into the cells 14 is dried, the component A is evaporated preferentially to the component B. Because the boiling point and the viscosity of the component A are lower than the boiling point and the viscosity of the component B. This makes it possible to raise the concentration of the component B in the ink 2. As a result, it is possible to increase a viscosity of the ink 2 discharged into the cells 14 abruptly.

The viscosity of the ink 2 increases abruptly, thereby changing the ink 2 to have the high viscosity as described above. Such an ink 2 is discharged into the cells 14. The surface of the discharged ink 2 in each cell 14 is stable due to the high viscosity of the ink 2. In other words, the surfaces of the ink 2 discharged into the cells 14 are made to be flat. In such a state, the liquid medium, namely the component B contained in the discharged ink 2 is evaporated to obtain coloring parts 12. In such an ink 2, it is possible to prevent the following problems from occurring reliably. One is a problem that when the liquid medium contained in the ink 2 is evaporated, convective flow occurs in the discharged ink 2. Another is a problem that bubbles generate from the discharged ink 2. The other is a problem that a thickness of the coloring parts 12 formed by discharging the ink 2 into the cells 14 becomes uneven. Therefore, according to the present invention, since such problems are solved, the thickness of the coloring parts 12 becomes even.

As a result, it is possible to sufficiently prevent uneven color or uneven density from generating at various portions of the manufactured color filter 1. Further, the manufactured color filters 1 can have more excellent uniformity in their characteristics.

In a color filter manufactured using the conventional ink for use in the color filter, a drying temperature of the ink discharged into cells is severely controlled. In this case, even if the drying temperature is simply changed slightly (temperature is set in the range of ±5° C.), drying characteristics of the ink discharged into the cells are changed. As a result, the characteristics become uneven among the manufactured color filters and the yield rate is lowered.

In contrast, even if a drying temperature is changed in a certain degree during the drying process of the method according to the present invention, it is possible to make variation of shapes of the surfaces of the ink 2 discharged into the cells 14. Further, the manufactured color filters 1 can have more excellent uniformity in their characteristics. Furthermore, it is also possible to increase the yield rate of products sufficiently.

In contrast, in the case where an ink does not satisfy the conditions mentioned above, it is impossible to obtain the superior effects as described above.

In the case where a liquid medium contained in the ink is constituted of only a component having a relatively low viscosity, it is possible to exhibit superior discharge characteristics of the ink discharged from nozzles of a droplet discharge head. However if such an ink is discharged into the cells, a viscosity of the ink increases gradually when drying the ink discharged into the cells.

In other words, the viscosity of the ink increases rapidly just before drying the ink discharged into the cells. Therefore, a thickness of the coloring parts formed in the cells becomes uneven. As a result, it is impossible to prevent uneven color or uneven density from generating in the coloring parts of the manufactured color filter.

On the other hand, in the case where the liquid medium contained in the ink is constituted of only a component having a relatively high viscosity, there are problems as follows. That is to say, a stable amount of the ink can not be discharged from the nozzles of the droplet discharge head. Therefore, clogging of the nozzles of the droplet discharge head is likely to occur, and therefore an amount of the ink discharged from the nozzles of the droplet discharge head becomes uneven. As a result, the thickness of the formed coloring parts becomes uneven therebetween.

Further, in the case where the liquid medium contained in the ink is constituted of two kinds of components of which the boiling points are different from each other and the viscosities are the same as each other, there are problems as follows. Such an ink is discharged into the cells, and then the discharged ink is dried. At this time, one component of which boiling point is lower than the boiling point of the other component is evaporated preferentially.

Thereafter, the other component is evaporated. In this way, the other component of which boiling point is higher than that of the one component is remaining in the ink. As a result, the viscosity of the ink increases gradually, to thereby form the coloring parts.

Since the thickness of the thus obtained coloring parts become uneven due to the gradually increased viscosity, it is impossible to prevent uneven color or the uneven density from generating in the coloring parts of the manufactured color filter.

Furthermore, in the case where the liquid medium contained in the ink is constituted of two kinds of components of which the boiling points are the same as each other and the viscosities are different from each other, there are problems as follows. In such an ink, a timing in which the two components are dried is changed measurably depending on difference of a latent heat of evaporation. However, the two components are dried at the same time. Therefore, the viscosity of the ink increases gradually during the drying process. As a result, it is impossible to obtain the superior effects as described above.

Furthermore, the liquid medium contained in the ink is constituted of two kinds of components of which boiling points are different from each other. And a viscosity of one component having a low boiling point is higher than a viscosity of the other component having a high boiling point. In this case, it is possible to exhibit superior discharge characteristics of the ink from nozzles of a droplet discharge head due to existence of the other component having the low viscosity.

However if the ink containing such a liquid medium is discharged into cells, the one component having a high viscosity is evaporated preferentially in the cells when drying the ink discharged into the cells. Therefore, it is impossible to make the surfaces of the ink of the formed coloring parts flat.

As described above, the ink 2 according to the present invention contains the component A and the component B of which boiling point is higher than a boiling point of the component A. In this case, when the boiling point of the component A under an atmospheric pressure is defined as T_{bp}(a) [° C.] and the boiling point of the component B under the atmospheric pressure is defined as T_{bp}(b) [° C.], it is preferred that T_{bp}(a) and T_{bp}(b) satisfy a relation represented by the formula: 20≦T_{bp}(b)−T_{bp}(a)≦70, more preferably 30≦T_{bp}(b)−T_{bp}(a)≦55, and even more preferably 35≦T_{bp}(b)−T_{bp}(a)≦50.

This makes it possible to increase the viscosity of the ink 2 discharged into the cells 14 in the drying process more reliably. Therefore, it is possible to obtain even thickness of the coloring parts 12 formed in the cells 14. As a result, it is possible to reliably prevent uneven color or uneven density from generating in the coloring parts 12 of the manufactured color filter 1. Therefore, the manufactured color filters 1 can have more excellent uniformity in their characteristics.

Further, when the viscosity of the component A at a temperature of 25° C. is defined as η(a) [mPa·s] and the viscosity of the component B at a temperature of 25° C. is defined as η(b) [mPa·s], it is preferred that η(a) and η(b) satisfy a relation represented by the formula: 1≦η(b)−η(a)≦15, more preferably 1.5≦η(b)−η(a)≦12.5, and even more preferably 3≦η(b)−η(a)≦8.

This makes it possible to increase the viscosity of the ink 2 discharged into the cells 14 in the drying process more reliably. Therefore, it is possible to obtain even thickness of the coloring parts 12 formed in the cells 14. Further, it is also possible to exhibit superior discharge characteristics (discharge stability) of the ink 2 discharged from the nozzles 118 of the droplet discharge head 114. As a result, it is possible to reliably prevent uneven color or uneven density from generating in the coloring parts 12 of the manufactured color filter 1. Therefore, the manufactured color filters 1 can have more excellent uniformity in their characteristics.

Hereinbelow, a constituent material constituting the ink 2 according to the present invention will be described in details.

In this regard, it is to be noted that the viscosity of each of the component A, the component B and the ink 2 can be measured according to JIS Z8809 using a vibration type viscometer.

Alternatively, the viscosity of each of the component A, the component B and the ink 2 may be measured using a rotational vibration type viscometer, a rotational type viscometer (E-type or B-type viscometer) and a cannon-fenske method (cannon-fenske type viscometer). In this specification, it is to be noted that a term “viscosity” means values obtained by the method and the viscometer as described above.

Coloring Agent

In general, a color filter 1 has coloring parts 12 having different colors (that is, three colors corresponding to red (R), green (G) and blue (B), namely RGB). Generally, a coloring agent is selected depending on the colors of the coloring parts to be formed. Examples of the coloring agent to constitute the ink 2 include various pigments and various dyes.

Examples of such various pigments include: C.I. PigmentReds 2, 3, 5, 17, 22, 23, 38, 81, 48:1, 48:2, 48:3, 48:4, 49:1, 52:1, 53:1, 57:1, 63:1, 112, 122, 144, 146, 149, 166, 170, 176, 177, 178, 179, 185, 202, 207, 209, 254, 101, 102, 105, 106, 108, and 108:1; C.I. PigmentGreens 7, 36, 15, 17, 18, 19, 26, and 50; C.I. PigmentBlues 1, 15, 15:1, 15:2, 15:3, 15:4, 15:6, 17:1, 18, 60, 27, 28, 29, 35, 36, and 80; C.I. PigmentYellows 1, 3, 12, 13, 14, 17, 55, 73, 74, 81, 83, 93, 94, 95, 97, 108, 109, 110, 129, 138, 139, 150, 151, 153, 154, 168, 184, 185, 34, 35, 35:1, 37, 37:1, 42, 43, 53, and 157; C.I. PigmentViolets 1, 3, 19, 23, 50, 14, and 16; C.I. PigmentOranges 5, 13, 16, 36, 43, 20, 20:1, and 104; C.I. PigmentBrowns 25, 7, 11, and 33; and the like.

Examples of such various dyes include: an azo dye, an anthraquinone dye, a condensed polynuclear aromatic carbonyl dye, an indigoid dye, a carbonium dye, a phthalocyanine dye, a methine dye, polymethine dye and the like.

Examples of such various dyes include: C.I. DirectReds 2, 4, 9, 23, 26, 28, 31, 39, 62, 63, 72, 75, 76, 79, 80, 81, 83, 84, 89, 92, 95, 111, 173, 184, 207, 211, 212, 214, 218, 221, 223, 224, 225, 226, 227, 232, 233, 240, 241, 242, 243, and 247; C.I. AcidReds 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396, and 397; C.I. ReactiveReds 3, 13, 17, 19, 21, 22, 23, 24, 29, 35, 37, 40, 41, 43, 45, 49, and 55; C.I BasicReds 12, 13, 14, 15, 18, 22, 23, 24, 25, 27, 29, 35, 36, 38, 39, 45, and 46; C.I. DirectViolets 7, 9, 47, 48, 51, 66, 90, 93, 94, 95, 98, 100, and 101; C.I. AcidViolets 5, 9, 11, 34, 43, 47, 48, 51, 75, 90, 103, and 126; C.I. ReactiveViolets 1, 3, 4, 5, 6, 7, 8, 9, 16, 17, 22, 23, 24, 26, 27, 33, and 34; C.I. BasicViolets 1, 2, 3, 7, 10, 15, 16, 20, 21, 25, 27, 28, 35, 37, 39, 40, and 48; C.I. DirectYellows 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161, and 163; C.I. AcidYellows 17, 19, 23, 25, 39, 40, 42, 44, 49, 50, 61, 64, 76, 79, 110, 127, 135, 143, 151, 159, 169, 174, 190, 195, 196, 197, 199, 218, 219, 222, and 227; C.I. ReactiveYellows 2, 3, 13, 14, 15, 17, 18, 23, 24, 25, 26, 27, 29, 35, 37, 41, and 42; C.I. BasicYellows 1, 2, 4, 11, 13, 14, 15, 19, 21, 23, 24, 25, 28, 29, 32, 36, 39, and 40; C.I. AcidGreen 16; C.I. AcidBlues 9, 45, 80, 83, 90, and 185; C.I. BasicOranges 21 and 23; and the like.

As the coloring agent, it is possible to use powders (particles) subjected to a surface treatment such as a lyophilic treatment, wherein the powders (particles) are constituted of the coloring agent as mentioned above. In this regard, it is to be noted that the lyophilic treatment means a treatment which improves affinity to the liquid medium described later.

This makes it possible to exhibit superior dispersibility and dispersion stability of the particles of the coloring agent in the ink 2. Examples of the surface treatment to the coloring agent include: a treatment which modifies the surfaces of the particles of the coloring agent with a polymer; and the like. Examples of such a polymer to be used for modifying the surfaces of the particles of the coloring agent include: polymers disclosed in JP-A-8-259876; commercially available polymers or commercially available oligomers for use in dispersing of various pigments; and the like.

Further, the coloring agent may be used in combination of two or more of the materials described above. In this case, one or more of the materials may be used as a complementary color agent.

In the ink 2, the coloring agent may be dissolved or dispersed in the liquid medium described later. In the case where the coloring agent is dispersed in the liquid medium, an average particle size of the coloring agent is preferably in the range of 20 to 200 nm, and more preferably in the range of 5 to 90 nm.

This makes it possible to exhibit superior light resistance of the color filter 1 manufactured by using the ink 2. Further, it is also possible to reliably exhibit superior dispersion stability of the coloring agent in the ink 2. Furthermore, it is also possible to reliably exhibit superior color development of the coloring parts 12 in the color filter 1.

An amount of the coloring agent contained in the ink 2 is preferably in the range of 2 to 20 wt %, and more preferably in the range of 3 to 15 wt %. If the amount of the coloring agent falls within above noted range, it is possible to exhibit superior discharge characteristics (discharge stability) of the ink 2 discharged from the nozzles 118 of the droplet discharge head 114. Further, it is also possible to exhibit superior durability of the manufactured color filter 1. Furthermore, it is also possible to reliably obtain appropriate color density in the manufactured color filter 1.

Liquid Medium

The liquid medium has a function of dissolving and/or dispersing the coloring agent as described above. In other words, the liquid medium serves as a solvent and/or a dispersant. Generally, most of the liquid medium is removed in a process of manufacturing of the color filter 1.

Such a liquid medium contains both a component A and a component B. A boiling point of the component B is higher than a boiling point of the component A. And a viscosity of the component B is higher than a viscosity of the component A.

In such a liquid material contained in the ink 2 discharged into the cells 14, the component A is evaporated earlier than the component B due to the difference between the boiling points thereof. Therefore, a viscosity of the ink 2 increases, thereby enabling a stable surface of the discharged ink 2 to be obtained due to its high viscosity. As a result, convective flow does not occur in the discharged ink 2 due to the high viscosity.

Further, bubbles also do not generate from the discharged ink 2. For these reasons, the thickness of the coloring parts 12 formed by discharging the ink 2 into the cells 14 becomes even. Further, it is also possible to reliably prevent uneven color or uneven density from generating in the coloring parts 12 of the manufactured color filter 1. Furthermore, the manufactured color filters 1 can have more excellent uniformity in their characteristics.

Component A

Examples of the component A to be used as the liquid medium contained in the ink 2 include: ester compound, an ether compound, hydroxyketon, carbonic diester, a cyclic amide compound and the like. Among these components A mentioned above, the following components A are preferable. The components A are: (1) ether such as a condensation between polyvalent alcohols (ethylene glycol, propylene glycol, butylenes glycol and glycerin) and alkyl ether such as methyl ether, ethyl ether, butyl ether and hexyl ether, which is obtained by using polyvalent alcohol or polyvalent alcohol ether; (2) ester such as methyl ester (at least one carboxylic acid thereof is esterified) which is obtained by using polyvalent carboxylic acid (succinic acid, and glutaric acid); (3) ether or ester which is obtained a compound (hydroxyl acid) having at least one hydroxyl group and one carboxyl group in the molecule thereof; (4) carbonic diester having a chemical structure of a compound which is obtained by using polyvalent alcohol and phosgene; (5) ester such as formate, acetate and propionate.

Examples of a compound to be used as the component A include 2-hydroxy-ethyl butyl ether, 2-hydroxy-propyl butyl ether, diethylene glycol monomethyl ether, diethylene glycol monoethyl ether, diethylene glycol monobutyl ether, ethylene glycol monobutyl ether, dipropylene glycol monomethyl ether, 3-methoxy-n-butyl acetate, butyl glycolate, ethylene glycol monohexyl ether, ethylene glycol dibutyl ether, γ-butyrolactone, diethylene glycol dimethyl ether, diethylene glycol ethyl methyl ether, diethylene glycol diethyl ether, N-methyl-2-pyrrolidone, ethylene glycol butyl methyl ether, bis(2-propoxymethyl)ether, diethylene glycol butyl methyl ether, diethylene glycol butyl ethyl ether, diethylene glycol butyl propyl ether, diethylene glycol ethyl propyl ether, diethylene glycol methyl propyl ether, diethylene glycol propyl ether acetate, diethylene glycol butyl ether acetate, triethylene glycol dimethyl ether, triethylene glycol ethyl methyl ether, triethylene glycol methyl ether acetate, triethylene glycol ethyl ether acetate, triethylene glycol propyl ether acetate, triethylene glycol butyl ether acetate, triethylene glycol butyl ethyl ether, triethylene glycol ethyl methyl ether, triethylene glycol ethyl propyl ether, triethylene glycol methyl propyl ether, propylene glycol methyl ether acetate, tripropylene glycol dimethyl ether, dipropylene glycol butyl methyl ether, dipropylene glycol methyl ether acetate, ethylene glycol 2-methyl hexyl ether, diethylene glycol monohexyl ether, diethylene glycol mono-2-ethylhexyl ether, ethylene glycol hexyl methyl ether, ethylene glycol dibutyl ether, ethylene glycol diacetate, diacetone alcohol, 1,3-butylene glycol diacetate, 3-ethoxy ethyl propionate, ethyl octanate, ethylene glycol monobutyl ether acetate, diethylene glycol propyl methyl ether, diethyl glutarate, 2-(2-methoxy-1-methylethoxy)-1-methyl ethyl acetate, cyclohexanol acetate, cyclohexyl acetate and the like.

In particular, the component A constituting the liquid medium is preferably diethylene glycol dimethyl ether, diacetone alcohol, 3-methoxy-n-butyl acetate, 3-ethoxy ethyl propyonate, diethylene glycol ethyl methyl ether, dipropylene glycol dimethyl ether, diethylene glycol diethyl ether, diethylene glycol dibutyl methyl ether, diethylene glycol propyl methyl ether, ethyl octanoate, cyclohexyl acetate, ethylene glycol monobutyl ether acetate, ethylene glycol monobutyl ether, 1,3-butylene glycol diacetate, diethylene glycol butyl ether acetate, ethylene glycol butyl methyl ether, ethylene glycol hexyl methyl ether, ethylene glycol dibutyl ether or 2-(2-methoxy-1-methylethoxy)-1-methyl ethyl acetate.

By using these compounds, the thickness of the formed coloring parts 12 becomes even. Further, the stable (constant) amount of the ink is discharged from nozzles 118 of the droplet discharge head 114. As a result, it is possible to reliably prevent uneven color or uneven density from generating in the coloring parts 12 of the manufactured color filter 1. Further, the manufactured color filters 1 can have more excellent uniformity in their characteristics.

The boiling point of the compound A under an atmospheric pressure (1 atom) is preferably in the range of 150 to 250° C., more preferably in the range of 155 to 200° C., and even more preferably in the range of 160 to 180° C.

If the boiling point of the compound A falls within above noted range, the component A is evaporated reliably from the ink discharged into the cells 14 in the drying process. Therefore, the viscosity of the ink 2 in the coloring parts 12 increases reliably due to existence of the compound B. As a result, the thickness of the formed coloring parts 12 becomes even. Further, it is also possible to reliably prevent clogging of the nozzles 118 of the droplet discharge head 114 which discharges (ejects) the ink 2 for use in the color filter 1. As a result, the productivity of the color filter 1 can be made excellent.

The viscosity of the compound A at a temperature of 25° C. is, but not limited thereto, preferably in the range of 0.5 to 2.5 mPa·s, and more preferably in the range of 0.8 to 1.5 mPa·s.

If the viscosity of the compound A falls within above noted range, the component A is evaporated reliably from the ink 2 discharged into the cells 14 in the drying process. Therefore, the viscosity of the ink 2 in the coloring parts 12 increases reliably due to existence of the compound B. As a result, the thickness of the formed coloring parts 12 becomes even. Further, it is also possible to reliably prevent variation of an discharged amount of the ink 2 from generating among the inks 2 having different colors.

At a temperature for drying the ink 2 discharged into the cells 14, a vapor pressure of the compound A is preferably higher than a vapor pressure of the compound B.

This makes it possible to preferentially evaporate the component A contained in the discharged ink 2 to the compound B during the drying process. Therefore, the viscosity of the ink 2 in the cells 14 is increased rapidly. As a result, the thickness of the formed coloring parts 12 becomes even. Further, it is possible to reliably prevent uneven color or uneven density from generating at various portions of the manufactured color filter 1. Furthermore, the manufactured color filters 1 can have more excellent uniformity in their characteristics.

The vapor pressure of such a compound A at a temperature of 25° C. is preferably 0.1 mmHg or higher, more preferably in the range of 0.2 to 5.0 mmHg, and even more preferably in the range of 0.3 to 4.0 mmHg.

If the vapor pressure of the compound A falls within above noted range, the compound A is evaporated from the ink 2 discharged into the cells 14 reliably. Therefore, the viscosity of the ink 2 discharged into the cells 14 increases in the drying process due to existence of the component B reliably. As a result, it is possible to reliably prevent clogging of the nozzles 118 of the droplet discharge head 114 which discharges the ink 2 for use in the color filter 1, thereby making excellent productivity of the color filter 1.

An amount of the compound A contained in the ink 2 is preferably in the range of 40 to 90 wt %, and more preferably in the range of 50 to 80 wt %.

This makes it possible to reliably increase the viscosity of the ink 2 discharged into the cells 14 in the drying process, and therefore the thickness of the formed coloring parts 12 becomes even.

Further, it is possible to exhibit superior discharge characteristics (discharge stability) of the ink 2 discharged from the nozzles 118 of the droplet discharge head 114 for use in the color filter 1. Further, it is also possible to exhibit superior durability of the manufactured color filter 1.

Furthermore, it is possible to reliably prevent uneven color or uneven density from generating in the coloring parts 12 of the manufactured color filter 1. Furthermore, the manufactured color filters 1 can have more excellent uniformity in their characteristics. Therefore, it is also possible to reliably obtain appropriate color density in the manufactured color filter 1.

Component B

Examples of the component B to be used as the liquid medium contained in the ink 2 include: ester compound, an ether compound, hydroxyl keton, carbonic diester, a cyclic amide compound, a monovalent alcohol or polyvalent alcohol compound and the like. Among these components B mentioned above, the following components B are preferable. The components B are: (1) ether such as a condensation between polyvalent alcohols (ethylene glycol, propylene glycol, butylenes glycol and glycerin) and alkyl ether such as methyl ether, ethyl ether, butyl ether and hexyl ether, which is obtained by using polyvalent alcohol or polyvalent alcohol ether; (2) ester such as methyl ester (at least one carboxylic acid thereof is esterified) which is obtained by using polyvalent carboxylic acid (succinic acid, and glutaric acid); (3) ether or ester which is obtained a compound (hydroxyl acid) having at least one hydroxyl group and one carboxyl group in the molecule thereof; (4) carbonic diester having a chemical structure of a compound which is obtained by using polyvalent alcohol and phosgene; (5) ester such as formate, acetate and propionate.

Examples of a compound to be used the component B include dipropylene glycol n-propyl ether, dipropylene glycol n-butyl ether, tripropylene glycol monomethyl ether, tripropylene glycol n-butyl ether, triethylene glycol monomethyl ether, triethylene glycol monoethyl ether, triethylene glycol monobutyl ether, diethylene glycol monobutyl ether, 2-(2-methoxy-1-methylethoxy)-1-methyl ethyl acetate, triethylene glycol dimethyl ether, triethylene glycol diacetate, diethylene glycol monoethyl ether acetate, 4-methyl-1,3-dioxolane-2-on, bis(2-butoxyethyl)ether, dimethyl glutarate, ethylene glycol di-n-butyrate, 1,3-butylene glycol diacetate, diethylene glycol monobutyl ether acetate, tetraethylene glycol dimethyl ether, 1,6-diacetoxy hexan, dipropylene glycol dimethyl ether, diethylene glycol dimethyl ether, 3-ethoxy ethyl propionate, diethylene glycol ethyl methyl ether, 3-methoxy butyl acetate, diethylene glycol diethyl ether, ethyl octanate, ethylene glycol monobutyl ether acetate, cyclohexyl acetate, diethyl succinate, ethylene glycol diacetate, propylene glycol diacetate, 4-hydroxy-4-methyl-2-pentanone, dimethyl succinate and the like.

In particular, the component B constituting the liquid medium is preferably ethylene glycol ethyl hexyl ether, tripropylene glycol methyl ether, triethylene glycol monomethyl ether, 4-methyl-1,3-dioxolane-2-on, diethylene glycol monobutyl ether, diethylene glycol monobutyl ether acetate, bis(2-buthoxyethyl)ether, 1,3-butylene glycol diacetate, triethylene glycol diacetate, ethylene glycol monobutyl ether acetate, triethylene glycol butyl methyl ether, nonyl alcohol, triacetine, propylene glycol phenyl ether or diethylene glycol monohexyl ether.

By using these compounds, the thickness of the formed coloring parts 12 becomes even. Further, the stable (constant) amount of the ink 2 is discharged from the nozzles 118 of the droplet discharge head 114. As a result, it is possible to reliably prevent uneven color or uneven density from generating at various portions of the manufactured color filter 1. Further, the manufactured color filters 1 can have more excellent uniformity in their characteristics.

The boiling point of the compound B under an atmospheric pressure (1 atom) is preferably in the range of 180 to 280° C., more preferably in the range of 200 to 260° C., and even more preferably in the range of 220 to 250° C.

If the boiling point of the compound B falls within above noted range, the component B is evaporated later than the component A in the ink 2 discharged into the cells 14 in the drying process. Therefore, the viscosity of the ink 2 in the coloring parts 12 increases reliably due to the viscosity of the compound B. As a result, the thickness of the formed coloring parts 12 becomes even. Further, it is also possible to reliably prevent clogging of the nozzles 118 of the droplet discharge head 114 which discharges the ink 2. As a result, the productivity can be made excellent.

The viscosity of the compound B at a temperature of 25° C. is, but not limited thereto, preferably in the range of 1.8 to 10.0 mPa·s, and more preferably in the range of 2.0 to 7.0 mPa·s.

If the viscosity of the compound B falls within above noted range, the viscosity of the ink 2 in the coloring parts 12 increases due to the viscosity of the compound B as described above. As a result, the thickness of the formed coloring parts 12 becomes even. Further, it is also possible to reliably prevent variation of an discharged amount of the ink 2 from generating among the inks 2 having different colors.

A vapor pressure of such a compound B at a temperature of 25° C. is preferably 0.08 mmHg or less, more preferably 0.05 mmHg or less, and even more preferably 0.03 mmHg or less.

If the vapor pressure of the compound B falls within above noted range, the compound B is evaporated later than the compound A in the ink 2 discharged into the cells 14. Therefore, the viscosity of the ink 2 discharged into the cells 14 increases in the drying process due to the viscosity of the component B reliably. As a result, it is possible to reliably prevent clogging of the nozzles 118 of the droplet discharge head 114, thereby making the excellent productivity of the color filter 1.

An amount of the compound B contained in the ink 2 is preferably in the range of 2 to 40 wt %, and more preferably in the range of 5 to 30 wt %.

This makes it possible to reliably increase the viscosity of the ink 2 discharged into the cells 14 in the drying process, and therefore the thickness of the formed coloring parts 12 becomes even.

Further, it is possible to exhibit superior discharge characteristics (discharge stability) of the ink 2 discharged from the nozzles 118 of the droplet discharge head 114. Further, it is also possible to exhibit superior durability of the manufactured color filter 1.

Furthermore, it is possible to reliably prevent uneven color or uneven density from generating at various portions of the manufactured color filter 1. Furthermore, the manufactured color filters 1 can have more excellent uniformity in their characteristics. Therefore, it is also possible to reliably obtain appropriate color density in the manufactured color filter 1.

The vapor pressure of the component A contained in such a liquid medium at a temperature of 25° C. is defined as P (a) [mmHg]. The vapor pressure of the component B contained in such a liquid medium at a temperature of 25° C. is also defined as P (b) [mmHg].

In this case, P(a) and P(b) preferably satisfy a relation represented by the formula: 1.2≦P(b)/P(a), more preferably 1.5≦P(b)/P(a)≦10.0, and even more preferably 2.0≦P(b)/P(a)≦8.0.

In this way, the vapor pressure of the compound A is higher than the vapor pressure of the compound B at the drying temperature of the ink 2. Therefore, since the compound A is evaporated from the ink 2 discharged into the cells 14 reliably, the viscosity of the discharged ink 2 can increase in the drying process reliably. As a result, the thickness of the formed coloring parts 12 becomes even.

Further, it is possible to reliably prevent uneven color or uneven density from generating at various portions of the manufactured color filter 1. Furthermore, the manufactured color filters 1 can have more excellent uniformity in their characteristics.

In the case where, the amount of the component A contained in the ink 2 is defined as X [wt %] and the amount of the component B contained in the ink 2 is also defined as Y [wt %]. X and Y preferably satisfy a relation represented by the formula: 1.0≦X/Y≦20, more preferably 1.2≦X/Y≦15, and even more preferably 1.5≦X/Y≦10.

This makes it possible to increase the viscosity of the ink 2 during the drying process reliably, and therefore the thickness of the formed coloring parts 12 becomes even. As a result, it is possible to reliably prevent uneven color or uneven density from generating at various portions of the manufactured color filter 1. Further, the manufactured color filters 1 can have more excellent uniformity in their characteristics.

Furthermore, it is possible to exhibit superior discharge characteristics (discharge stability) of the ink 2 discharged from the nozzles 118 of the droplet discharge head 114. Furthermore, it is also possible to exhibit superior durability of the manufactured color filter 1.

Dispersant

A dispersant may be contained in the ink 2 for use in the color filter 1. Even if the ink 2 contains a pigment having low dispersibility, it is possible to exhibit superior dispersion stability reliably. As a result, it is possible to exhibit superior preservability or storage stability of the ink 2.

Examples of such a dispersant include a cationic surfactant, an anionic surfactant, a nonionic surfactant, an ampholytic surfactant, a silicone type surfactant, a fluorochemical surfactant and the like.

Examples of such surfactants include: polyoxy ethylene alkyl ether such as polyoxyethylene lauryl ether, polyoxyethylene stearyl ether, and polyoxyethylene oleyl ether; polyoxyethylene alkyl phenyl ether such as polyoxyethylene n-octyl phenyl ether, and polyoxyethylene n-nonyl phenyl ether; polyethylene glycol diester such as polyethylene glycol dilaurate, and polyethylene glycol distearate; sorbitan fatty acid ester; fatty acid modified-polyester; tertiary amine modified-polyurethane; polyethylene imine; a product such as KP (produced by Shin-Etsu Chemical Co., Ltd.), Poly-Flow (produced by KYOEISHA CHEMICAL CO., LTD.), FTOP (produced by JEMCO Inc.), MEGAFACK (produced by DIC Corporation), Flolard (produced by Sumitomo 3M Limited), AsahiGuard and Surflon (produced by ASAHI GLASS CO., LTD.), Disperbyk (produced by BYK Japan KK), Solsperse 3000, 5000, 11200, 12000, 13240, 13650, 13940, 16000, 17000, 18000, 20000, 21000, 22000, 24000SC, 24000GR (produced by LUBRIZOL JAAN Ltd.), and Surfinol and Dynol (produced by Air Products Inc.); and the like.

Further, examples of the dispersant also include a compound having a cyamelide ring. Use of these compounds as the dispersant makes it possible to reliably exhibit superior dispersibility of the pigment in the ink 2. Additionally, use of these compounds as the dispersant also makes it possible to reliably exhibit superior discharge stability of the ink 2 discharged from the nozzles 118 of the droplet discharge head 114.

Furthermore, examples of the dispersant also include a compound having a structure represented by the following chemical structures (I) and (II). Use of such a compound as the dispersant makes it possible to reliably exhibit superior dispersibility of the coloring agent (pigment) in the ink 2. Additionally, use of such a compound as the dispersant also makes it possible to reliably exhibit superior discharge stability of the ink 2 discharged from the nozzles 118 of the droplet discharge head 114.

Chemical Structure (I)

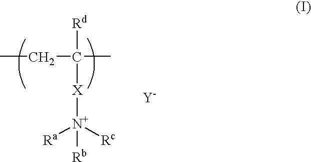

where each of R^{a}, R^{b} and R^{c} independently represents a hydrogen atom or a ring or a chain hydrocarbon group which may be substituted, two or three in R^{a}, R^{b} and R^{c} may form one or two ring structure formed by bonding each other, R^{d} represents a hydrogen atom or a methyl group, X represents a bivalent connecting group, and Y— represents a pairing anion.

Chemical Structure (II)

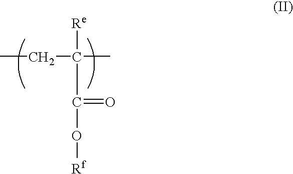

where R^{e} represents a hydrogen atom or a methyl group, R^{f} represents a ring or a chain alkyl group which may have a substituted group, an aryl group which may have a substituted group, or an aralkyl group which may have a substituted group.

An amount of the dispersant contained in the ink 2 is preferably in the range of 0.5 to 15 wt %, and more preferably in the range of 0.5 to 8 wt %.

Resin Material

Generally, a resin material (binder resin) is contained in the ink 2 for use in the color filter 1. Inclusion of the resin material in the ink 2 makes it possible to exhibit superior adhesion between a coloring layer (ink 2) and a substrate 11 in the manufactured color filter 1. Therefore, it is possible to exhibit superior durability of the color filter 1.

The resin material may be of any kind of resin material. Examples of such a resin material to be contained in the ink 2 include various thermoplastic resins, various thermosetting resins and the like. The resin material is preferably an acrylic resin and an epoxy resin which are obtained by porimerizing a polyfunctional molecule.

This is because the acrylic resin and the epoxy resin have characteristics in that transparency thereof is high, hardness thereof is high and a amount of heat contraction thereof is low. Therefore, use of the acrylic resin or the epoxy resin makes it possible to exhibit superior adhesion between the coloring parts 12 and the substrate 11.

In the epoxy resin, the resin material is also preferably an epoxy resin having both a silyl acetate structure (SiOCOCH₃) and an epoxy structure in the chemical structure thereof. Use of such an epoxy resin makes it possible to discharge (eject) droplets of the ink 2 by an ink-jet reliably. Additionally, inclusion of such an epoxy resin in the ink 2 makes it possible to exhibit superior adhesion between a coloring layer (ink 2) and the substrate 11. Therefore, it is possible to exhibit superior durability of the color filter 1.

An amount of the resin material contained in the ink is preferably in the range of 0.5 to 10 wt %, and more preferably in the range of 1 to 5 wt %. If the amount of the resin material falls within above noted range, it is possible to exhibit superior discharge characteristics (discharge stability) of the ink 2 discharged from the nozzles 118 of the droplet discharge head 114. Further, it is also possible to exhibit superior durability of the manufactured color filter 1. Furthermore, it is also possible to reliably obtain appropriate color density in the manufactured color filter 1.

In contrast, if the amount of the resin material is smaller than the lower limit value noted above, the discharge characteristics of the ink 2 is deteriorated. Additionally, hardness of the formed coloring parts 12 is also lowered, thereby deteriorating durability of the manufactured color filter 1. On the other hand, if the amount of the resin material exceeds the upper limit value noted above, it is impossible to reliably obtain appropriate color density in the manufactured color filter 1.

Other Components

Various other components may be contained in the ink 2 for use in the color filter 1, if necessary.

Examples of such other components (other additive) include: various crosslinking agents; various polymerization initiators; a dispersion auxiliary such as a blue pigment derivative which includes a copper phthalocyanine derivative and a yellow pigment derivative; a filler such as glass and alumina; a polymer such as polyvinyl alcohol, polyethylene glycol monoalkyl ether, poly fluoro alkyl acrylate; an adherence accelerating agent such as vinyl trimethoxy silane, vinyl triethoxy silane, vinyl tris(2-methoxyethoxy)silane, N-(2-aminoethyl)-3-aminopropyl methyl dimethoxy silane, N-(2-aminoethyl)-3-aminopropyl trimethoxy silane, 3-aminopropyl triethoxy silane, 3-glycidoxy propyl trimethoxy silane, 3-glycidoxy propyl methyl dimethoxy silane, 2-(3,4-epoxy cyclohexyl)ethyl trimethoxy silane, 3-chloro propyl methyl dimethoxy silane, 3-chloro propyl trimethoxy silane, 3-methacryloxy propyl trimethoxy silane, and 3-mercapto propyl trimethoxy silane; an antioxidant such as 2,2-thiobis(4-methyl-6-t-butylphenol) and 2,6-di-t-butylphenol; an ultraviolet absorber such as 2-(3-t-butyl-5-methyl-2-hydroxyphenyl)-5-chlorobenzo triazole and alkoxy benzophenone; an aggregation inhibitor such as sodium polyacrylate; a stabilizer of discharge performance of an ink-jet such as methanol, ethanol, i-propanol, n-butanol, and glycerin; a surfactant such as FTOP-EF301, FTOP-EF303 and FTOP-EF352 (produced by JEMCO Inc.), MEGAFACK F171, MEGAFACK F172, MEGAFACK F173, MEGAFACK F178K (produced by DIC Corporation), Flolard FC430, Flolard FC431 (produced by Sumitomo 3M Limited), AsahiGuard AG710, Surflon S-382, Surflon SC-101, Surflon SC-102, Surflon SC-103, Surflon SC-104, Surflon SC-105, Surflon SC-106 (produced by ASAHI GLASS CO., LTD.), KP341 (produced by Shin-Etsu Chemical Co., Ltd.), Poly-Flow No. 75 and Poly-Flow No. 95 (produced by KYOEISHA CHEMICAL CO., LTD.); and the like.

A thermal acid generating agent and an acid crosslinking agent may also be contained in the ink 2. The thermal acid generating agent is a component which generates an acid by heat. Examples of the thermal acid generating agent include: an onium salt such as a sulfonium salt, a benzothiazolium salt, an ammonium salt and a phosphonium salt; and the like. Among the thermal acid generating agent mentioned above, the thermal acid generating agent is preferably the sulfonium salt and the benzothiazolium salt.

A viscosity of the ink 2 at a temperature of 25° C. is, but not limited thereto, preferably in the range of 5 to 12 mPa·s, and more preferably in the range of 6 to 10 mPa·s.

The viscosity of the ink 2 at the temperature of 25° C. falls within above noted range, it is possible to exhibit superior discharge characteristics (discharge stability) of the ink 2 discharged from the nozzles 118 of the droplet discharge head 114. As a result, since the liquid medium contained in the ink 2 is evaporated as described above, it is possible to reliably prevent uneven color or uneven density from generating at various portions of the manufactured color filter 1.

Further, the manufactured color filters 1 can have more excellent uniformity in their characteristics. Furthermore, it is also possible to reliably prevent clogging of the nozzles 118 of the droplet discharge head 114 which discharges the ink 2, thereby making the excellent productivity of the color filter 1.

Ink Set

As described above, the ink 2 is used for manufacturing the color filter 1 by the ink-jet. Generally, the color filter has coloring parts having predetermined different colors (that is, three colors of RGB corresponding to three primary colors of light). The coloring parts 12 having predetermined different colors are formed by using the inks 2 having colors which correspond to the predetermined different colors of the coloring parts 12, respectively. That is to say, an ink set that contains the inks 2 having the different colors is used in manufacturing of the color filter 1. In other words, each ink contained in the ink set is constituted from the ink 2 according to the present invention as described above.

In each of such inks having the different colors, color density of a color of one coloring agent contained therein is different from color density of a color of the other coloring agent depending on the kinds of coloring agent. Therefore, the amounts of the coloring agent and the liquid medium contained in one ink 2 are different from the amounts of the coloring agent and the liquid medium contained in the other ink 2 for the purpose of adjustment of optical transparency and hue of each color of the inks 2.

If coloring parts having different colors are formed by using the conventional ink set, each of the inks having different colors contained in the ink set is dried under the different drying conditions. Therefore, it is difficult that each thickness of all the coloring parts of different colors is even.

In contrast, in the ink set containing the ink 2 according to the present invention, each of the inks 2 having different colors is dried in the wide range of the drying temperature in the drying process. Therefore, each thickness of all the coloring parts 12 of different colors is even.

Color Filter

Next, a description will be made with regard to one example of a color filter which is manufactured using inks for use in a color filter (ink set) as described above.

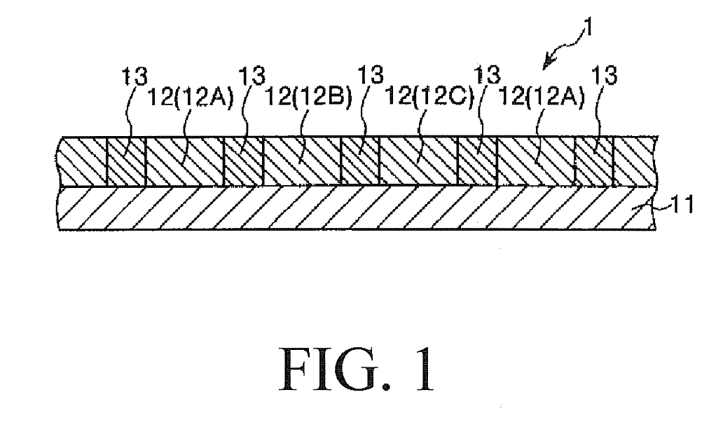

FIG. 1 is a cross-sectional view which shows a preferred embodiment of the color filter 1 according to the present invention.

As shown in FIG. 1, the color filter 1 includes a substrate 11 and coloring parts 12 formed on the substrate 11 by using the inks 2 for use in a color filter 1 described above (here in after, simply referred to as “ink 2” or “inks 2” on occasion). The coloring parts 12 include first coloring parts 12A, second coloring parts 12B and third coloring parts 12C which have different colors, respectively. Further, partitioning walls 13 are also formed on the substrate 11 between the adjacent coloring parts 12.

Substrate

The substrate 11 is a plate-shaped member having a light transmissive property, and has a function of supporting the coloring parts 12 and the partitioning walls 13.

In this regard, it is preferred that the substrate 11 is formed of a substantially transparent material. This makes it possible to form a clearer image by the lights transmitting through the color filter 1.

Further, it is also preferred that the substrate 11 is formed of a constituent material having good heat resistance and mechanical strength. By using such a constituent material, it is possible to prevent deformation from occurring by heat applied in manufacturing the color filter 1. Examples of such a constituent material include glass, silicon, polycarbonate, polyester, aromatic polyamide, polyamideimide, polyimide, norbornene based ring-opening copolymer and its hydrogen additive and the like.

Coloring Parts

The coloring parts 12 are formed using the inks 2 as described above.

Since the coloring parts 12 are formed using the inks 2 as described above, there is small variation in properties among the respective pixels. Therefore, the manufactured color filter 1 can have high reliability because generation of uneven color and uneven density are reliably prevented.

Each of the coloring parts 12 is provided in a cell 14 which is a region surrounded by the partitioning walls 13 which will be described later in detail.

The first coloring parts 12A, second coloring parts 12B, and third coloring parts 12C have different colors from each other. For example, the first coloring parts 12A may be formed into red filter regions (R), the second coloring parts 12B may be formed into green filter regions (G), and the third coloring parts 12C may be formed into blue filter regions (B).

In this example, a set of the first coloring part 12A, second coloring part 12B, and third coloring part 12C having different colors constitutes one pixel. In the color filter 1, a predetermined large number of pixels are arranged in lateral and longitudinal directions thereof. For example, in the case where the color filter 1 is a color filter for a high vision TV display, 1366×768 pixels are arranged in lateral and longitudinal directions thereof.

In the case where the color filter 1 is a color filter for a full high vision TV display, 1920×1080 pixels are arranged in lateral and longitudinal directions thereof. Further, in the case where the color filter 1 is a color filter for a super high vision TV display, 7680×4320 pixels are arranged in lateral and longitudinal directions thereof. In this regard, it is to be noted that the color filter 1 may be of the type that additional pixels are arranged outside of an effective area thereof.

Partitioning Walls

As described above, the partitioning walls (banks) 13 are provided between the adjacent coloring parts 12. By the provision of the partitioning walls 13, it is possible to prevent inks 2 of the adjacent coloring parts 12 from being mixed to each other, and thus it is possible to display a clear color image reliably.

The partitioning walls 13 may be formed of a transparent material, but it is preferable that the partitioning walls 13 are formed of a material having a light shading property. This makes it possible to display a color image having excellent contrast. A color of the partitioning walls 13 (light shading part) is not particularly limited to a specific color, but it is preferable that the partitioning walls 13 are colored with black. This also makes it possible to display a color image having excellent contrast.

The height of the partitioning walls 13 is also not limited to a specific height, but it is preferable that the height of the partitioning walls 13 is higher than the film thickness of each of the coloring parts 12. This makes it possible to prevent inks 2 of the adjacent coloring parts 12 from being mixed to each other. The actual thickness of the partitioning walls 13 is preferably in the range of 0.1 to 10 μm, and more preferably in the range of 0.5 to 3.5 μm. This also makes it possible to prevent inks 2 of the adjacent coloring parts 12 from being mixed to each other. Further, it is also possible to obtain an image display apparatus 1000 with the color filter 1 and an electronic apparatus with the color filter 1 which have excellent view angle characteristics.

The partitioning walls 13 may be formed of any constituent material, but it is preferable that the partitioning walls 13 are mainly formed of a resin material. This makes it possible to easily form partitioning walls 13 having a desired shape. Further, in the case where the partitioning walls 13 have a function of the light shading part, the constituent material thereof may contain a material having a light absorbing property such as carbon black.

Manufacturing Method of Color Filter

Next, a description will be made with regard to one example of a manufacturing method of a color filter 1.

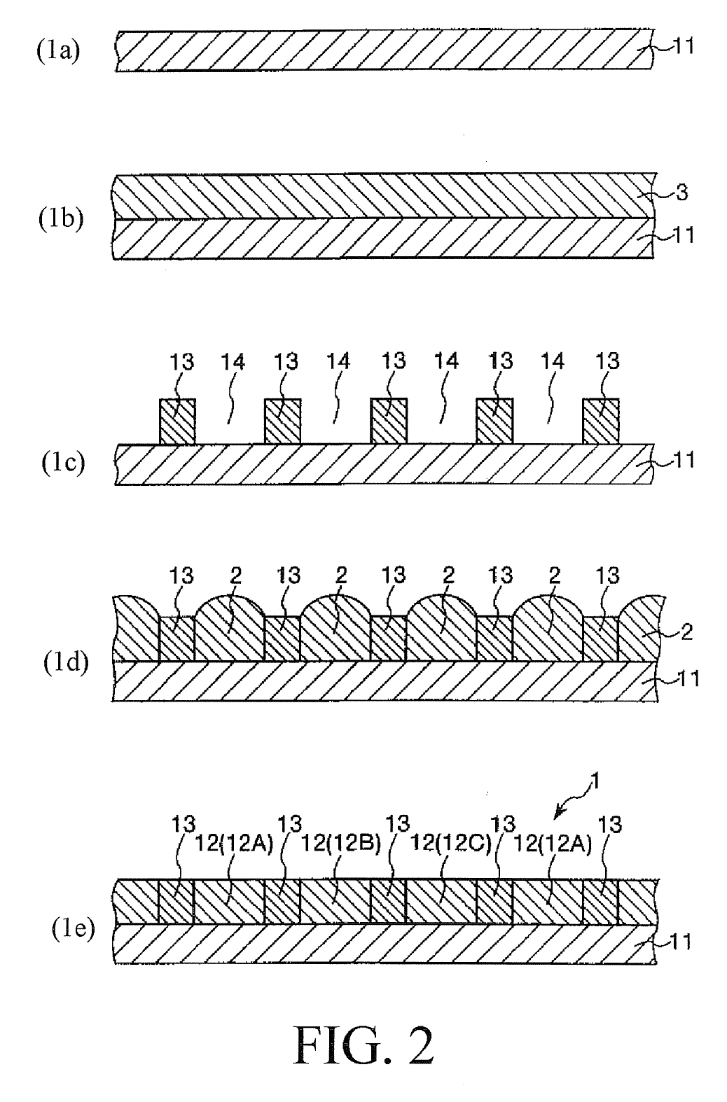

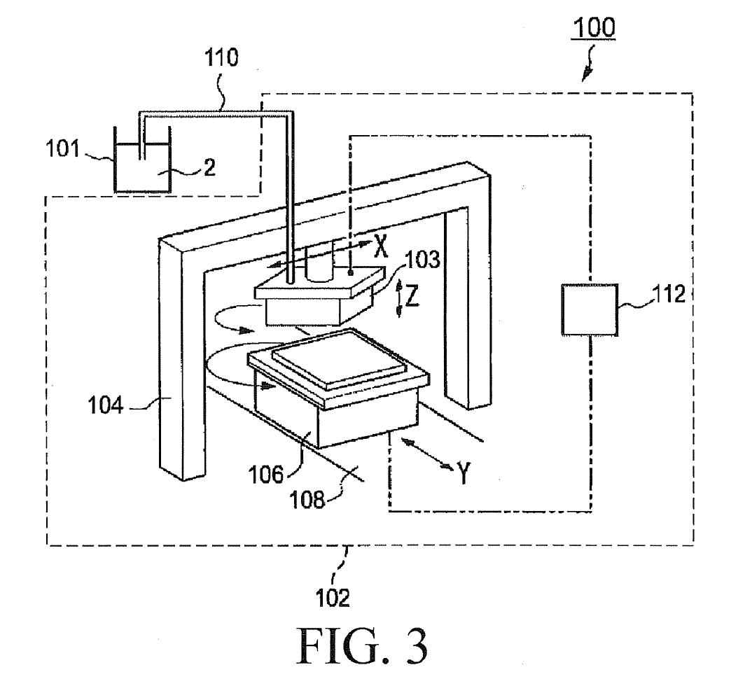

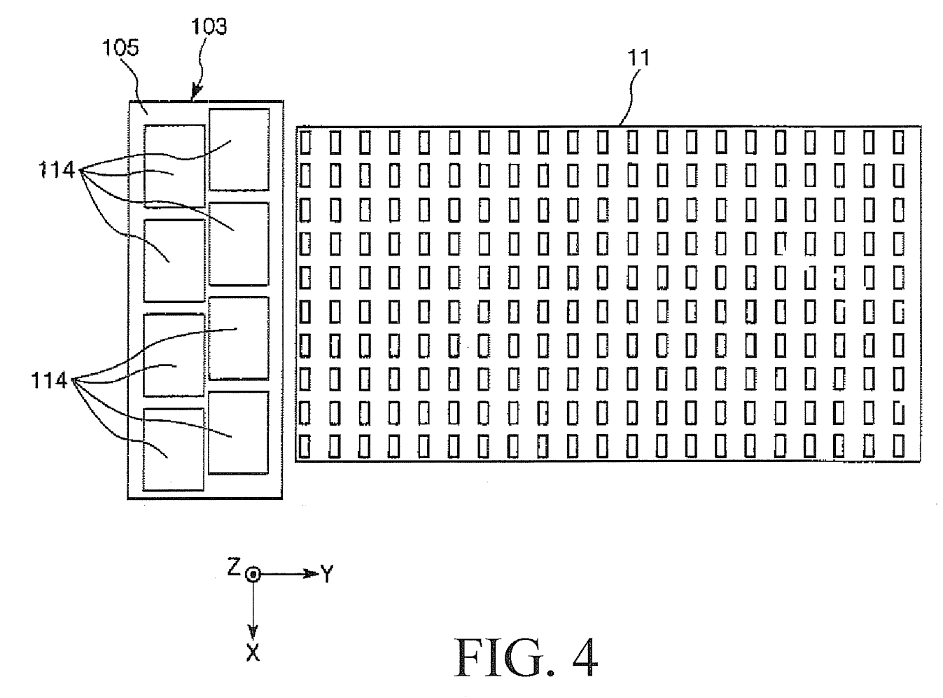

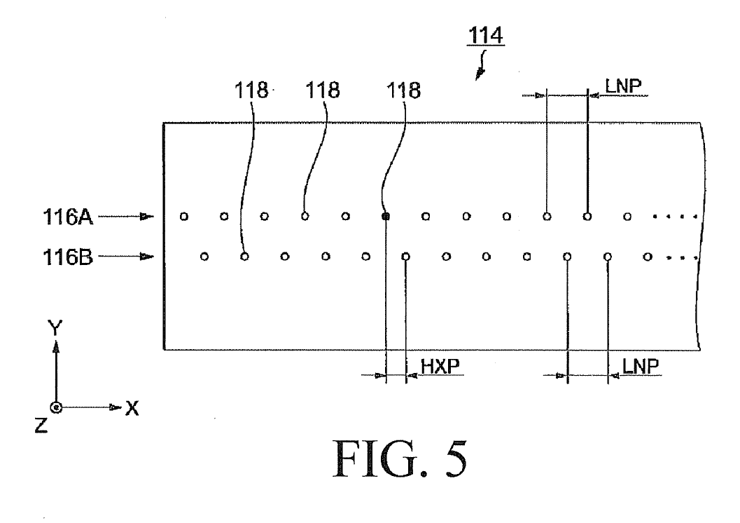

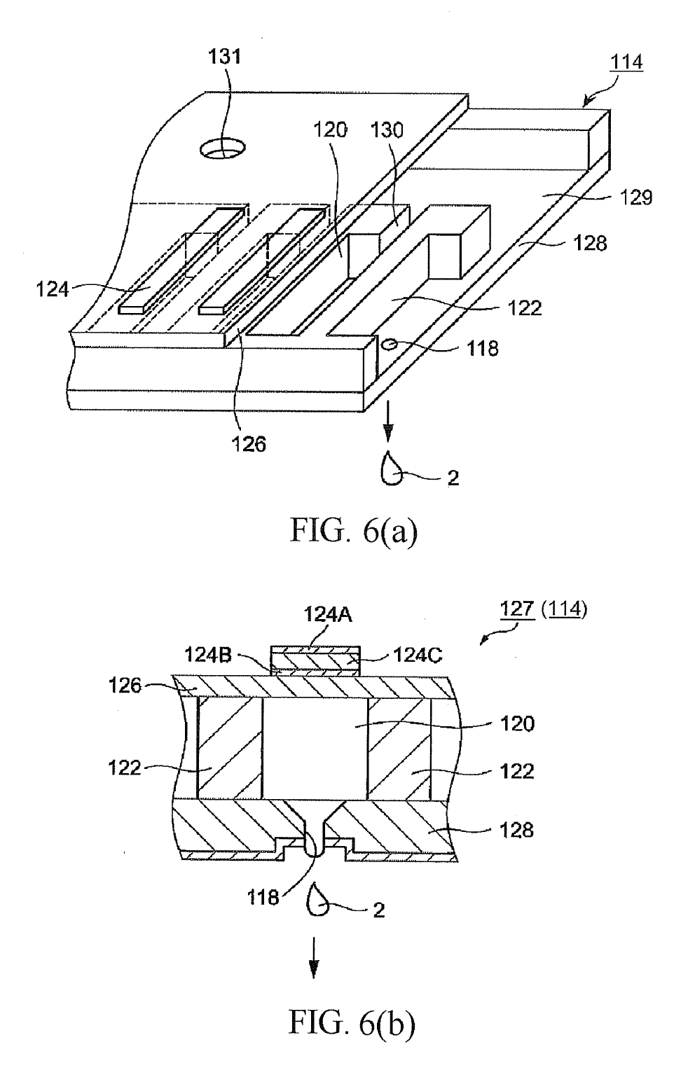

FIG. 2 is a cross sectional view which shows a manufacturing method of the color filter; FIG. 3 is a perspective view which shows a droplet discharge apparatus used in manufacturing the color filter; FIG. 4 is an illustration of a droplet discharge means of the droplet discharge apparatus shown in FIG. 3, which is viewed from the side of a stage of the apparatus; FIG. 5 is a bottom view of a droplet discharge head of the droplet discharge apparatus shown in FIG. 3; and FIG. 6(a) is a perspective view of the droplet discharge head of the droplet discharge apparatus shown in FIG. 3, in which a part of the head is removed, and FIG. 6(b) is a cross sectional view of the droplet discharge head of the droplet discharge apparatus.

As shown in FIG. 2, the manufacturing method of this embodiment includes: (1a) a substrate preparing step for preparing a substrate 11, (1b, 1c) a partitioning wall forming step for forming partitioning walls 13 on the substrate 11, (1d) an ink supplying step for supplying inks 2 into regions surrounded by the partitioning walls 13, and (1e) a coloring part forming step for removing a liquid medium from the inks 2 to form the coloring parts 12 of a solid state.

Substrate Preparing Step (1a)

First, a substrate 11 is prepared (1a). The substrate 11 prepared in this step has been preferably subjected to a washing treatment. Further, the substrate 11 prepared in this step may be one which has been subjected to a primary treatment such as a chemical treatment using a silane coupling agent or the like, a plasma treatment, ion plating, sputtering, a vapor phase reaction method, a vacuum deposition, or the like.

Partitioning Wall Forming Step (1b, 1c)

Next, a radio-sensitive composition for forming the partitioning walls 13 is applied to one of the entire surfaces of the substrate 11 to thereby form a coating layer 3 (1b). In this regard, it is to be noted that a pre-bake treatment may be carried out after applying the radio-sensitive composition onto the surface of the substrate 11, as necessary. The pre-bake treatment may be carried out under the conditions that, for example, a heating temperature is in the range of 50 to 150° C. and a heating time is in the range of 30 to 600 seconds.

Thereafter, the surface of the substrate 11 is irradiated with radio rays through a photomask to carry out a photo exposure treatment (PEB), and then a development treatment using an alkali development solution to thereby form the partitioning walls 13 on the substrate 11. The PEB may be carried out under the conditions that, for example, a heating temperature is in the range of 50 to 150° C., a heating time is in the range of 30 to 600 seconds, and a radio ray irradiation intensity is in the range of 1 to 500 mJ/cm².

Further, the development treatment may be carried out by a liquid application method, a dipping method, a vibratory immersion method, or the like. Furthermore, the development treatment time may be in the range of 10 to 300 seconds, for example. Moreover, after the development treatment, a post-bake treatment may be carried out, if necessary. This post-bake treatment can be carried out under the conditions that, for example, a heating temperature is in the range of 150 to 280° C. and a heating time is in the range of 3 to 120 minutes.

Ink Supplying Step (1d)

Next, the inks 2 as described above are supplied to cells 14 surrounded by the partitioning walls 13 by an ink-jet (1d).

This step is carried out using a plurality of inks 2 having colors corresponding to the colors of the coloring parts 12 to be formed. In this case, since the partitioning walls 13 are provided between the adjacent cells 14, it is possible to reliably prevent two or more inks 2 from being mixed to each other.

Supply of the inks 2 into the cells 14 is carried out using a droplet discharge apparatus 100 as shown in FIG. 3 to FIG. 6.

This step is carried out in a state that the droplet discharge apparatus 100 is placed in a chamber (thermal chamber) of which temperature is set to a predetermined temperature. Normally, the temperature of the chamber in which the droplet discharge apparatus 100 is placed is set at a temperature in the range of 20 to 26° C. By setting the temperature of the chamber within this range, a temperature control of the chamber can be carried out relatively easily.

Further, temperature variations or changes at various portions of the inside of the chamber which are caused by heat generated by the droplet discharge apparatus 100 can be made to be relatively small. Further, an amount of energy required by the temperature control such as an electrical power and the like can be also reduced. Furthermore, since a temperature inside a clean room is normally set within the above range, an existing clean room can be preferably used for manufacturing the color filter 1.

Moreover, since the inks 2 of the present invention have small variation in their viscosity even though temperature changes occur, it is possible to make an discharge stability of the inks excellent without severely controlling the temperature inside the chamber. That is, it is possible to suppress variations in the amounts of the discharged droplets without severely controlling the temperature inside the chamber. However, normally, the temperature inside the chamber is set within the range of 0.5 to 1.5° C. (±0.25 to ±0.75° C.).

As described above, the temperature inside the chamber in which the droplet discharge apparatus 100 is placed is preferably set in the range of 21 to 25° C., and more preferably in the range of 22 to 24° C. This makes it possible to exhibit the effects described above conspicuously. Further, an discharge stability of the inks 2 can be made especially excellent.

As shown in FIG. 3, the droplet discharge apparatus 100 used in this step includes a tank 101 which stores an ink 2 having a predetermined color, a tube 110, and an discharging and scanning section 102 to which the ink 2 is supplied from the tank 101 through the tube 110. The discharging and scanning section 102 includes a droplet discharge means 103 which is provided with a plurality of droplet discharge heads 114 (ink-jet heads) mounted on a carriage 105, a first position control means 104 (moving means) which controls a position of the droplet discharge means 103, and a stage 106 which supports the substrate 11 on which the partitioning walls 13 have been formed in the previous step (herein after, simply referred to as “the substrate 11”), a second position control means 108 (moving means) which controls a position of the stage 106, and a control means 112. The tank 101 and the droplet discharge heads 114 of the droplet discharge means 103 are coupled with the tube 110 so that the ink 2 is supplied to the respective droplet discharge heads 114 from the tank 101 by means of compressed air.

The first position control means 104 moves the droplet discharge means 103 in an X-axis direction and a Z-axis direction which is perpendicular to the X-axis direction in response to signals from the control means 112. Further, the first position control means 104 also has a function of rotationally moving the droplet discharge means 103 about an axis parallel to the Z-axis. In this embodiment, the Z-axis is a direction parallel to a vertical direction (that is, a direction of the gravity acceleration).

The second position control means 108 moves the stage 106 in the X-axis direction and a Y-axis direction perpendicular to both the X-axis direction and the Z-axis direction in response to signals from the control means 112. Further, the second position control means 108 also has a function of rotationally moving the stage 106 about an axis parallel to the Z-axis.

The stage 106 has a surface which is parallel to both the X-axis direction and the Y-axis direction. Further, the stage 106 is configured so that the substrate 11 having the cells 14 to which the inks 2 are to be supplied is supported or fixedly mounted on the surface of the stage 106.

As described above, the droplet discharge means 103 is moved by the first position control means 104 in the X-axis direction. On the other hand, the stage 106 is moved by the second position control means 108 in the Y-axis direction. Namely, the relative position of the droplet discharge heads 114 with respect to the stage 106 is changed by the first position control means 104 and the second position control means 108 (that is to say, the substrate 11 supported on the stage 106 and the droplet discharge means 103 are relatively moved to each other).

The control means 112 is configured so as to receive data that represents relative positions to which the inks 2 are to be discharged from an external data processing apparatus.

As shown in FIG. 4, the droplet discharge means 103 includes the droplet discharge heads 114 which have substantially the same structure, and the carriage 105 that supports these droplet discharge heads 114. In this embodiment, the number of the droplet discharge heads 114 provided on the droplet discharge means 103 is eight. Each of the droplet discharge heads 114 has a bottom surface in which a plurality of nozzles 118 (which will be described later in detail) are formed.

The bottom surface of the droplet discharge head 114 is formed into a rectangular shape having a pair of long sides and a pair of short sides. The bottom surface of the droplet discharge head 114 held by the droplet discharge means 103 faces the stage 106, and the long sides and short size of the droplet discharge head 114 are in parallel with the X-axis direction and the Y-axis direction, respectively.

As shown in FIG. 5, each of the droplet discharge heads 114 has a plurality of nozzles 118 arranged in the X-axis direction. These nozzles 118 are arranged so that a nozzle pitch HXP between the adjacent nozzles 118 becomes a predetermined value. The value of the nozzle pitch HXP is not limited to a specific value, but it may be set to the range of 50 to 90 μm, for example.

Here, it is to be noted that “the nozzle pitch HXP in the X-axis direction in each of the droplet discharge heads 114” corresponds to a nozzle pitch of a plurality of nozzle images which are obtained by projecting all the nozzles 118 of the droplet discharge head 114 onto a plane on the X-axis from the Y-axis direction.

In this embodiment, the plurality of nozzles 118 include a nozzle array 116A and a nozzle array 116B which extend along the X-axis direction. The nozzle array 116A and the nozzle array 116B are arranged parallel to each other through a predetermined spacing therebetween. Further, in this embodiment, each of the nozzle array 116A and nozzle array 116B includes 90 nozzles 118 which are arranged along the X-axis direction so as to form a single line with a predetermined spacing LNP therebetween. The value of the LNP is not limited to a specific value, but it can be set to the range of 100 to 180 μm.

The nozzles 118 of the nozzle array 116B are shifted by a half pitch (½ of the LNP) with respect to the nozzles 118 of the nozzle array 116A in the X-axis direction (right direction in FIG. 5). Therefore, the nozzle pitch HXP of the droplet discharge head 114 in the X-axis direction is a half length of the nozzle pitch LNP of the nozzle array 116A (or the nozzle array 116B).

In other words, a nozzle line density of the droplet discharge head 114 in the X-axis direction is a double of a nozzle line density of the nozzle array 116A (or the nozzle array 116B) in the X-axis direction. In this regard, it is to be noted that in this specification the terms “nozzle line density in the X-axis direction” correspond to the number of nozzle images per a unit length which are obtained by projecting all the nozzles 118 of the droplet discharge head 114 onto a plane on the X-axis from the Y-axis direction. Of course, the number of the nozzle arrays of the droplet discharge head 114 is not limited to two. The droplet discharge head 114 may include M nozzle arrays.

In this regard, it is to be noted that M is an integer of one or more. In this case, in each of the M nozzle arrays, the plurality of nozzles 118 are arranged with a pitch having a length of M times of the nozzle pitch HXP. Further, in the case where M is an integer equal to or greater than two, one of the M nozzle arrays is shifted by i times of the nozzle pitch HXP in the X-axis direction with respect to the (M−1) nozzle array so that the nozzles 118 of the one nozzle array do not overlap with the nozzles 118 of the (M−1) nozzle array. Here, it should be noted that i is an integer between one and (M−1).

As described above, in this embodiment, each of the nozzle array 116A and the nozzle array 116B includes 90 nozzles 118, respectively, and therefore each droplet discharge head 114 includes 180 nozzles 118. However, in the nozzle array 116A, five nozzles of each of the opposite ends of the nozzle array 116A are formed into “disable nozzles”.

Likewise, five nozzles of each of the opposite ends of the nozzle array 116B are also formed into “disable nozzles”. From these 20 disable nozzles of the nozzle array 116A and the nozzle array 116B, no ink is discharged. Therefore, in the 180 nozzles 118 of each droplet discharge head 114, only 160 nozzles other than the 20 disable nozzles function as nozzles for discharging the ink 2.

As shown in FIG. 4, in the droplet discharge means 103, a first row of the droplet discharge head 114 including four droplet discharge heads 114 and a second row of the droplet discharge heads 114 including four droplet discharge heads 114 are arranged so as to form two parallel rows in the X-axis direction.

In more details, one of the droplet discharge heads 114 in the first row is arranged so as to partially overlap with the corresponding droplet discharge head 114 in the second row when viewed from the Y-axis direction taking the presence of the disable nozzles of these droplet discharge heads 114 into account. Because of such an arrangement of the droplet discharge heads 114, the droplet discharge means 103 is configured so that the nozzles 118 from which the inks 2 can be discharged are arranged continuously with the nozzle pitch HXP over the entire length of the substrate 11 in the X-axis direction.

As described above, in the droplet discharge means 103 of this embodiment, the droplet discharge heads 114 are disposed so as to cover the entire length of the substrate 11 in the X-axis direction. However, in the present invention, the droplet discharge means 103 may be configured so as to cover a part of the entire length of the substrate 11 in the X-axis direction.

As shown in FIG. 6(a) and FIG. 6(b), each of the droplet discharge heads 114 is constructed from an ink-jet nozzle head. In more details, each of the droplet discharge heads 114 is provided with a vibration plate 126 and a nozzle plate 128. Between the vibration plate 126 and the nozzle plate 128, there is provided a liquid storage 129, which is always to be filled with the ink 2 supplied from the tank 101 through a hole 131.

Further, between the vibration plate 126 and the nozzle plate 128, a plurality of partition walls 120 are provided. A portion defined by the vibration plate 126, nozzle plate 128 and a pair of partition walls 120 forms a cavity 120. Since each cavity 120 is provided so as to correspond to the corresponding nozzle 118, the number of the cavities 120 is the same as that of the nozzles 118. Each of the cavities 120 is adapted to be supplied with the inks 2 from the liquid storage 129 through a supply space 130 positioned between the pair of partition walls 120.

On the vibration plate 126, vibrating elements 124 are provided so as to correspond to the respective cavities 120. Each of the vibrating elements 124 includes a piezoelectric element 124C and a pair of electrodes 124A, 124B between which the piezoelectric element 124C is provided. By supplying a driving voltage across the electrodes 124A, 124B, the ink 2 is discharged from the corresponding nozzle 118. In this regard, it is to be noted that the shape of each nozzle is configured so that the ink 2 is discharged from the nozzle 118 in the Z-axis direction.

The control means 112 (see FIG. 3) may be configured so that signals are applied to the plurality of vibrating elements 124, respectively, to drive vibrating elements 124 independently to each other. In other words, the volume of the ink 2 discharged from each of the nozzles 118 may be controlled in each of the nozzles 118 in response to the signal from the control means 112. Further, the control means 112 may selectively determine nozzles 118 that can discharge the inks 2 during the ink applying and scanning operation and nozzles 118 that cannot discharge the inks 2 during the ink applying and scanning operation.

In this specification, a portion that includes one nozzle 118, a cavity 120 corresponding to the nozzle 118 and a vibrating element 124 corresponding to the cavity 120 may be referred to as “discharge portion”. When this term “discharge portion” is used, one droplet discharge head 114 has discharge portions of which number is the same as the number of the nozzles 118.

By using the droplet discharge apparatus 100 as described above, the inks 2 corresponding to colors of the coloring parts 12 of the color filter 1 are supplied to the cells 14. By using such an apparatus, it is possible to efficiently and effectively supply the inks 2 to the cells 14.

Further, since each of the inks 2 contains the component A as described above as a liquid medium, an discharged amount of the ink 2 is equalized, and therefore it is possible to accurately control an amount of droplets of the ink 2 to be discharged into each of the cells 14. Furthermore the ink 2 that has been discharged into each cell 14 is held in the cell 14 with a state that its surface be flat. Therefore, it is possible to effectively prevent generation of uneven color and uneven density from occurring at various portions of the manufactured color filter 1.

Further, it is also possible to effectively prevent variation in characteristics from occurring among the manufactured color filters 1. In this regard, it is to be noted that although the droplet discharge apparatus 100 is shown in FIG. 3 to have a tank 101 that stores the ink 2 for one color and a tube 110 connected thereto, it goes without saying that the droplet discharge apparatus 100 may have these components three or more so as to correspond to the colors of the coloring parts 12 of the color filter 1.

Alternatively, in the manufacturing method of the color filter 1 according to the present invention, a plurality of droplet discharge apparatuses 100 corresponding to the plurality of colors of the inks 2 may be employed.

Further, it is also to be noted that in the droplet discharge head 114 of the present invention, an electrostatic actuator may be employed as the driving element instead of the piezoelectric element. Alternatively, the droplet discharge head 114 may employ an electrothermal conversion element as the driving element, in which the ink 2 is discharged by utilizing thermal expansion of a material of the ink by the electrothermal conversion element.

Coloring Part Forming Step (1e)

Next, by drying the inks 2 that have been discharged into the cells 14, the liquid medium is evaporated or removed from the inks 2 in the cells 14 to thereby form coloring parts 12 of a solid state (1e). As a result, a color filter 1 can be obtained.

When the inks 2 are dried in this way, the component A that has a lower viscosity and a lower boiling point than those of the component B contained in the inks 2 are preferentially evaporated. Therefore, since the concentration of the component B is raised, the viscosity of the inks 2 in the cells 14 is also increased abruptly.

When the inks 2 in the cells 14 have such a high viscosity due to the abruptly increased viscosity, the shape of the ink 2 in each cell 14 becomes stable, and then the liquid medium remaining in the inks of which surfaces have been flat is evaporated, thereby the coloring parts 12 are formed in the cells 14.

In the inks 2 described above, when the liquid medium is evaporated in this step, it is possible to reliably prevent occurrence of convective flow in the inks 2 in the cells 14 as well as generation of bubbles in the inks 2 in the cells 14 which would be causes of variations in thicknesses of the coloring parts 12 to be formed. As a result, it is possible to reliably prevent generation of uneven color and uneven density at various portion of the color filter 1 to be manufactured, thereby enabling the uniformity in the properties among the manufactured color filters 1 to be excellent.

Further, in this step, when the inks 2 that have been discharged into the cells 14 are dried, the component A contained in the inks 2 may be evaporated under the constant drying condition (such as drying temperature, drying atmosphere, and the like). Alternatively, the component A may be evaporated with changing the drying condition two or more times.

For example, in the case where the drying condition is changed twice in this step, the inks 2 that have been discharged into the cells 14 are dried at a relatively low temperature to thereby evaporate the component A of a lower boiling point contained in the inks 2 in preference to the component B of a higher boiling point.

Thereafter, the drying temperature is raised, and under the temperature a part of the component B and the remaining component A are evaporated. This makes it possible reliably to prevent the component B from being excessively evaporated from the inks 2 that have been discharged into the cells 14 reliably, so that the coloring parts 12 to be formed can contain an appropriate amount of the component B. As a result, each of the coloring parts 12 is plasticized more appropriately, and therefore the manufactured color filter 1 can display an image having an excellent image quality stably regardless of use environment thereof.

Further, by using such a manufacturing method as described above, it is possible to prevent the constituent material of the color filter 1 from being deteriorated by a heat applied during the drying process more reliably. In this regard, it is to be noted that, generally, under the condition that a latent heat of evaporation of liquid components is equal to each other, if boiling points of these liquid components differ by 30° C., an evaporation rate of the liquid component having a high boiling point is lowered about half of the evaporation rate of the liquid component having a low boiling point.

Likewise, if the boiling points of the liquid components differ by 50° C., the evaporation rate of the liquid component having the high boiling point is lowered about one-third of the evaporation rate of the liquid component having the high boiling point. This means that according to the progressing of the drying, the viscosity of the liquid is increased since an amount of the high viscosity component remaining in the liquid is relatively increased.

In the case where a latent heat of evaporation of the liquid component having the low boiling point is smaller than that of the liquid component of the high boiling point, the difference between the evaporation rates becomes large further.

Specifically, when a boiling point of the component A is defined as T_{bp}(a) [° C.] and a boiling point of the component B which is higher than the boiling point of the component A is defined as T_{bp} (b) [° C.], a temperature T1 at the start of the drying preferably lies in the range represented by the formula: T_{bp}(a)−80≦T1≦T_{bp}(a)−20, and more preferably lies in the range represented by the formula: T_{bp}(a)−60≦T1≦T_{bp}(a)−30. This makes it possible to evaporate the component A having a low boiling point contained in the inks 2 in preference to the component B having a high boiling point reliably. As a result, it is possible to make the surfaces of the inks 2 in the cells 14 flat more reliably.

Further, as described above, after preferentially evaporating the component A contained in the inks 2, the liquid medium remaining in the inks 2 is removed at a predetermined temperature T2, wherein the temperature T2 preferably lies in the range represented by the formula: T_{bp} (a)−60≦T2≦T_{bp} (b)+50, and more preferably lies in the range represented by the formula: T_{bp}(a)−50≦T2≦T_{bp} (b)+20. This makes it possible to maintain a state that the surfaces of the inks 2 in the cells 14 is made to be flat more reliably. As a result, the thickness of each of the coloring parts 12 to be formed can be made more uniformly.

Further, in this step, the resin material may be reacted with any curing component or the like, if necessary. The removal of the liquid component can be carried out by heating the inks 2, for example. Such heating may be carried out in a state that the substrate 11 with the inks 2 is placed in an atmosphere of a reduced pressure. This makes it possible to progress the removal of the liquid medium efficiently, while preventing occurrence of an adverse effect to the substrate 11 and the like. In addition, this step may be carried out under irradiation with radio rays. This makes it possible to progress the reaction of the resin material and the curing component efficiently.

Image Display Apparatus

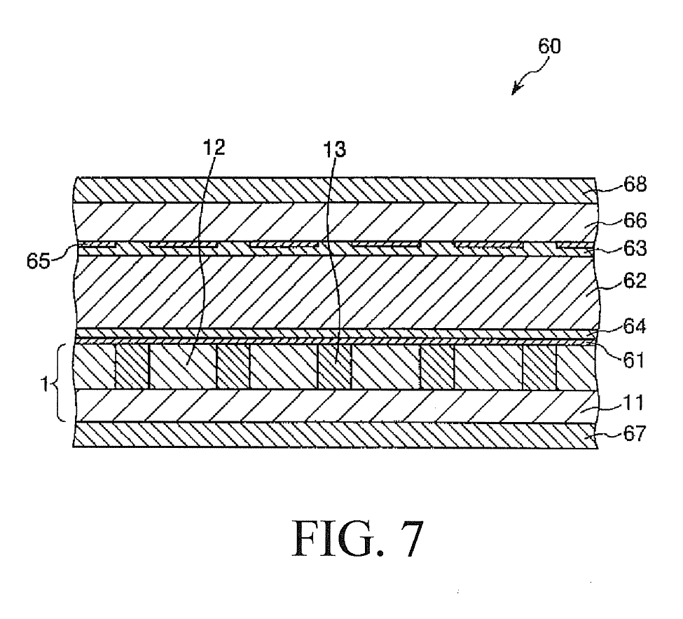

Next, a description will be made with regard to a preferred embodiment of a liquid crystal display apparatus which is one example of an image display apparatus (electro-optic apparatus) provided with the color filter 1 of the present invention. FIG. 7 is a cross-sectional view which shows a preferred embodiment of the image display apparatus.

As shown in this figure, the liquid crystal display apparatus 60 includes the color filter 1, a substrate (opposed substrate) 66 which is provided on the side of the color filter 1 on which the coloring parts 12 are formed, a liquid crystal layer 62 which contains a liquid crystal filled in a space between the color filter 1 and the substrate 66, a polarizing plate 67 provided on a surface of the substrate 11 of the color filter 1 which does not face the liquid crystal layer 62, and a polarizing plate 68 provided on a surface of the substrate 66 which does not face the liquid crystal layer 62.

Further, a common electrode 61 is provided on the coloring parts 12 and the partitioning walls 13 of the color filter 1, and pixel electrodes 65 are provided on a surface of the substrate 66 that faces the liquid crystal layer 62 in a matrix manner. In addition, an orientation film 64 is provided between the common electrode 61 and the liquid crystal layer 62, and an orientation film 63 is provided between the substrate 66 (including the pixel electrodes 65) and the liquid crystal layer 62.

The substrate 66 has a light transmitting property for visible light, and it is formed from a glass substrate, for example. The common electrode 61 and the pixel electrodes 65 are also formed of a constituent material having a light transmitting property for visible light, and they may be formed of ITO or the like, for example.

Further, though not shown in this figure, a number of switching elements (e.g. TFTs, that is, thin film transistors) are provided so as to correspond to the respective pixel electrodes 65. With this structure, by controlling a voltage applying state between the common electrode 61 and the respective pixel electrodes 65 that correspond to the respective coloring parts 12, it is possible to control light transmitting properties of lights through regions corresponding to the respective coloring parts 12 (respective pixel electrodes 65).

In the liquid crystal display apparatus 60, light emitted from a back light not shown in this figure is incident on the apparatus 60 from the side of the polarizing plate 68 (from the upper side in FIG. 7). The light that has passed through the liquid crystal layer 62 and then entered into the respective coloring parts 12 (coloring parts 12A, coloring parts 12B, coloring parts 12C) of the color filter 1 is emitted from the side of the polarizing plate 67 as lights having different colors corresponding to the colors of the respective coloring parts 12 (coloring parts 12A, coloring parts 12B, coloring parts 12C).

As described above, the coloring parts 12 are formed using the inks 2 for color filter of the present invention, variations in the properties among the respective colors and the respective pixels are preferably suppressed. As a result, the liquid crystal display apparatus 60 can have sufficiently wide color reproducible range, and thus the liquid crystal apparatus 60 can display images having less uneven color and uneven density stably.

Electronic Apparatus

The image display apparatus (electro-optical apparatus) 1000 provided with the color filter 1 can be applied to image display portions of various electronic apparatuses.

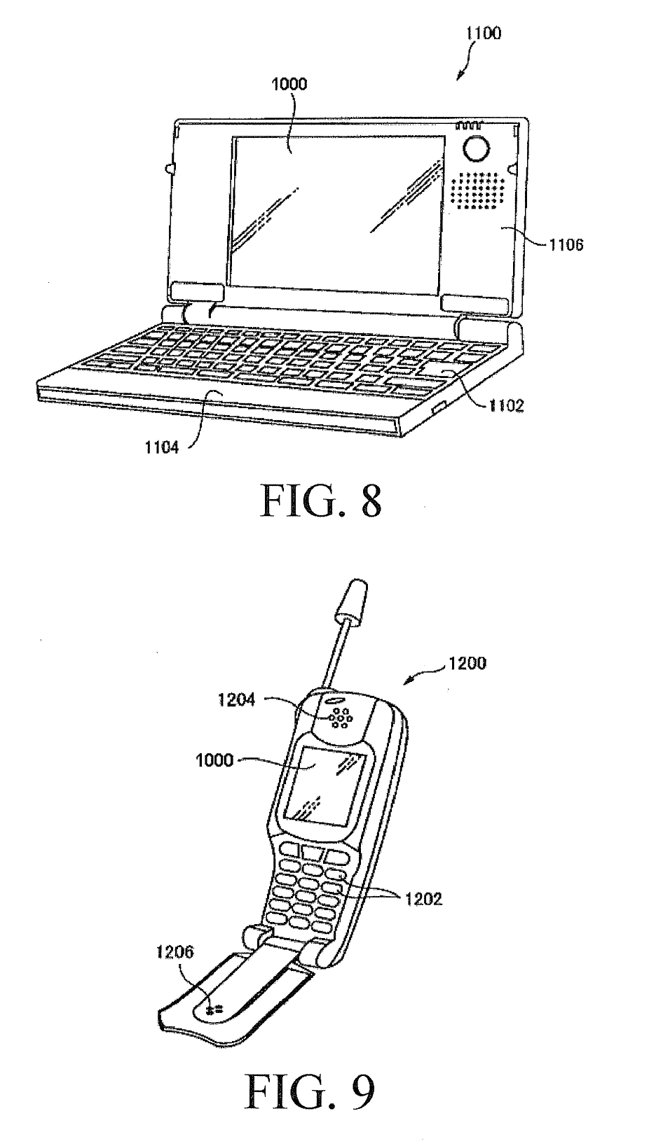

FIG. 8 is a perspective view of a personal computer of a mobile type (or a notebook type) which is one example of the electronic apparatus of the present invention.

In this figure, a personal computer 1100 is comprised of a main body 1104 provided with a keyboard 1102 and a display unit 1106 provided with a display. The display unit 1106 is rotatably supported by the main body 1104 via a hinge structure.

In the personal computer 1100, for example, the display unit 1106 includes the image display apparatus 1000 described above.

FIG. 9 is a perspective view which shows the structure of a mobile phone (including the personal handyphone system (PHS)) which is another example of the electronic apparatus according to the present invention.

The mobile phone 1200 shown in this figure includes a plurality of operation buttons 1202, an earpiece 1204, a mouthpiece 1206, and a display unit 1106 comprised of the image display apparatus 1000.

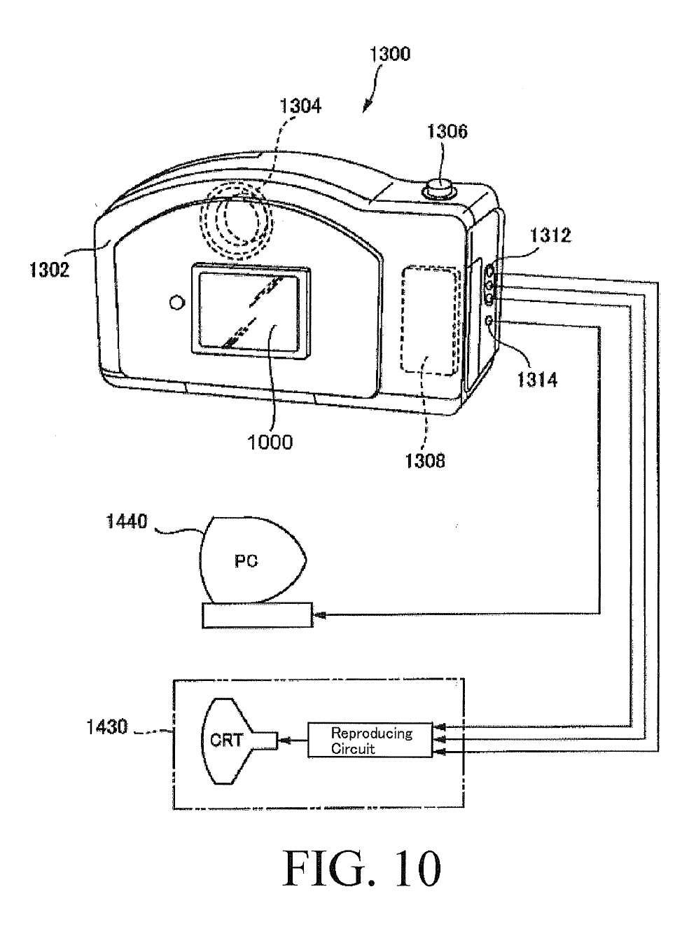

FIG. 10 is a perspective view which shows the structure of a digital still camera which is yet another example of the electronic apparatus according to the present invention. In this drawing, interfacing to external devices is simply illustrated.

In a conventional camera, a silver salt film is exposed to the optical image of an object. On the other hand, in the digital still camera 1300, an image pickup device such as a CCD (Charge Coupled Device) generates an image pickup signal (or an image signal) by photoelectric conversion of the optical image of an object.

In the rear surface of a case (or a body) 1302 of the digital still camera 1300, there is provided a display comprised of the image display apparatus 1000 which provides an image based on the image pickup signal generated by the CCD. That is, the display functions as a finder which displays the object as an electronic image.

In the inside of the case, there is provided a circuit board 1308. The circuit board 1308 has a memory capable of storing an image pickup signal.

In the front surface of the case 1302 (in FIG. 10, the front surface of the case 1302 is on the back side), there is provided a light receiving unit 1304 including an optical lens (an image pickup optical system) and a CCD.

When a photographer presses a shutter button 1306 after checking an object image on the display, an image pickup signal generated by the CCD at that time is transferred to the memory in the circuit board 1308 and then stored therein.

Further, in the side surface of the case 1302 of the digital still camera 1300, there are provided a video signal output terminal 1312 and an input-output terminal for data communication 1314. As shown in FIG. 10, when necessary, a television monitor 1430 and a personal computer 1440 are connected to the video signal output terminal 1312 and the input-output terminal for data communication 1314, respectively. In this case, an image pickup signal stored in the memory of the circuit board 1308 is outputted to the television monitor 1430 or the personal computer 1440 by carrying out predetermined operations.

Examples of the electronic apparatus according to the present invention may include, in addition to the personal computer (which is a personal mobile computer), the mobile phone, and the digital still camera described above with reference to FIG. 8 to FIG. 10, a television (TV) set (television with a liquid crystal display), a video camera, a view-finer or monitor type of video tape recorder, a laptop-type personal computer, a car navigation device, a pager, an electronic notepad (which may have communication facility), an electronic dictionary, an electronic calculator, a computerized game machine, a word processor, a workstation, a videophone, a security television monitor, an electronic binocular, a POS terminal, an apparatus provided with a touch panel (e.g., a cash dispenser located on a financial institute, a ticket vending machine), medical equipment (e.g., an electronic thermometer, a sphygmomanometer, a blood glucose meter, an electrocardiograph monitor, ultrasonic diagnostic equipment, an endoscope monitor), a fish detector, various measuring instruments, gages (e.g., gages for vehicles, aircraft, and boats and ships), a flight simulator, various monitors, a projection display such as a projector, and the like.

Among these electronic apparatuses mentioned above, a display size of TVs tends to be enlarged, and this tendency becomes more conspicuously in recent years. In electronic apparatuses having such a large size display (e.g., monitor or screen having a diagonal size of 80 cm or more), in the case where a color filter 1 manufactured using the conventional ink for color filter is employed, there is a problem in that uneven color and uneven density are highly likely to occur. However, by using the inks 2 of the present invention to such a color filter 1 for a large size display, such a problem as described above can be prevented reliably. In other words, when the inks 2 of the present invention are applied to electronic apparatuses having such a large size display, the effects of the present invention are exhibited more conspicuously.

In the foregoing, the present invention was described based on the preferred embodiments thereof, but the present invention is not limited thereto. For example, in the embodiment described above, after the inks 2 corresponding to the respective coloring parts 12 are supplied to the cells 14, the liquid medium is removed from the inks 2 in the cells 14 at once. That is, in the embodiment described above, the coloring part forming step is carried out just one time. However, the coloring part forming step may be carried out repeatedly for each of the inks 2 the colors of the respective coloring parts 12.

Further, in the color filter 1 of the present invention, a protective film may be provided on the coloring parts 12 formed on the substrate 11. This makes it possible to effectively prevent the coloring parts 12 and other portions from being damaged or deteriorated. Furthermore, any parts or components of the color filter 1, the image display apparatus and the electronic apparatus described above may be replaced with other parts or components that can exhibit the same or similar functions, and other additional parts or components may be added thereto.

### EXAMPLES

### 1 Preparation of Inks for Use in Color Filter

### Example 1

First, a resin A as a resin material was synthesized as follows. 320 parts by weight of n-hexane, 86 parts by weight of methacrylic acid and 111 parts by weight of triethylamine were added into a four-neck flask to obtain a mixture. Thereafter, a thermometer, a reflux condenser, a stirrer and a nitrogen inlet nozzle were assembled to each mouth of the four-neck flask, respectively. Then, 120 parts by weight of trimethylchlorosilane was dropped into the four-neck flask with stirring the mixture in a state that the mixture in the four-neck flask was cooled with ice water. At this time, a temperature of the mixture was adjusted so that the temperature thereof is 25° C. or lower. Thereafter, the mixture added the trimethylchlorosilane was stirred for 1 hour at a temperature of 25° C. to obtain a hydrochloride of trimethylchlorosilane.

Next, the obtained hydrochloride of trimethylchlorosilane was filtered to obtain a filtrate, then n-hexane was removed from the obtained filtrate under the reduced pressure to obtain a crude product. Thereafter, the crude product was distilled under the reduced pressure to obtain a pure product, namely an ethylene monomer having a silyl-acetate structure.

Next, 90 parts by weight of dipropylene glycol methyl ether acetate as a solvent and 10 parts by weight of diethylene glycol monohexyl ether were added into another four-neck flask to obtain a mixture. Thereafter, a thermometer, a reflux condenser, a stirrer and a nitrogen inlet nozzle were assembled to each mouth of the four-neck flask, respectively. Then, a temperature of the mixture was raised to 60° C. with stirring the mixture. Thereafter, a mixture of 27 parts by weight of the ethylene monomer, 30 parts by weight of glycidyl methacrylate, 38 parts by weight of styrene and 6 parts by weight of 2,2′-azobis-(2,4-dimethylvaleronitrile) was dropped into the four-neck flask for 1 hour.

After the completion of the drop, the four-neck flask was left for 1 hour at a temperature of 60° C. Then, parts by weight of 2,2′-azobis-(2,4-dimethylvaleronitrile) was added into the four-neck flask with stirring to obtain a solution. The solution was further stirred for 6 hours at a temperature of 60° C. to obtain a crude product. Thereafter, the crude product was distilled under the reduced pressure to remove the ethylene monomer of no reaction. As a result, the resin A solution is obtained as an epoxy resin having the silyl-acetate structure and an epoxy structure.

Next, a liquid medium of 90 parts by weight of dipropylene glycol methyl ether acetate and 10 parts by weight of diethylene glycol monohexyl ether (liquid constituting a liquid medium) was prepared in a vessel. 4.9 pars by weight of Disperbyk-161 (produced by BYK Japan KK, a compound having a cyamelide ring) as a dispersant, 6.9 parts by weight of C.I. PigmentGreen 36 and 2.9 parts by weight of C.I. PigmentYellow 150 as coloring agents were added into the vessel to obtain a mixture. Thereafter, the mixture was subjected to a beads mill (zirconia beads having a diameter of 0.65 mm was used) to thereby disassociate the C.I. PigmentGreen 36:6 and the C.I. PigmentYellow 150. As a result, a pigment dispersion liquid was obtained.

Thereafter, 4.4 parts by weight of the resin A solution and 95.6 parts by weight of the pigment dispersion liquid were mixed to obtain an ink of a green color (green ink (G-ink)) for use in a color filter. An average particle size of each of the C.I. PigmentGreen 36 and the C.I. PigmentYellow 150 in the green ink was 160 nm.

An ink of red color (red ink (R-ink)) for use in a color filter was manufactured in the same manner as the green ink except that the C.I. PigmentGreen 36 as the coloring agent was changed to a C.I. PigmentRed 254 and the solvent to synthesize the resin A, the liquid medium to prepare the pigment dispersion liquid and the amount of each component were changed to those for the red ink shown in Table 1. An average particle size of each of the C.I. PigmentRed 254 and the C.I. PigmentYellow 150 in the red ink was 160 nm.

Further, an ink of blue color (blue ink (B-ink)) for use in a color filter was manufactured in the same manner as the green ink except that the C.I. PigmentGreen 36 and the C.I. pigment Yellow 150 as the coloring agents were changed to a C.I. PigmentBlue 15:6 and the solvent to synthesize the resin A, the liquid medium to prepare the pigment dispersion liquid and the amount of each component were changed to those for the blue ink shown in Table 1. An average particle size of the C.I. Pigment Blue 15:6 in the blue ink was 160 nm.

### Examples 2 to 10

In each of Examples 2 to 10, inks of green, red, blue colors (ink set) were manufactured in the same manner as in the Example 1 except that the kind of liquid medium and the amount of each component were changed to those shown in Table 1 and Table 2. In the case where the composition of the liquid medium was changed, a composition of a solvent which was used for synthesizing a resin A was also changed according to the change of the composition. Thus the resin A synthesized by using the changed solvent was used for manufacturing the inks having different colors.

### Comparative Examples 1 to 5

In each of Comparative Examples 1 to 5, inks of green, red, blue colors (ink set) were manufactured in the same manner as in the Example 1 except that the kind of liquid medium and the amount of liquid medium were changed to those shown in Table 2. In the case where the composition of the liquid medium was changed, a composition of a solvent which is used for synthesizing a resin A was also changed according to the change of the composition. Thus the resin A synthesized by using the changed solvent was used for manufacturing the inks having different colors.

In each of the Examples 1 to 10 and the Comparative Examples 1 to 5, each of the composition and the viscosity of the inks of the green, red and blue colors, characteristics of the liquid medium (component A and component B), a kind and an amount of the coloring agent, a kind of and an amount of the resin material, and a kind of and an amount of the dispersant were shown in Table 1 and Table 2.

In this regard, it is to be noted that in Table 1 and Table 2 the C.I. PigmentRed 254 is shown as “PR254”, the C.I. PigmentRed 177 is shown as “PR177”, the C.I. PigmentGreen 36 is shown as “PG36”, the C.I. PigmentBlue 15:6 is shown as “PB15:6”, the C.I. PigmentYellow 150 is shown as “PY150”, the resin A is shown as “a”, the Disperbyk-161 (dispersant) is shown as “b”, dipropylene glycol methyl ether acetate is shown as “A”, ethylene glycol monobutyl ether acetate is shown as “B”, 3-methoxy butyl acetate (methoace) is shown as “C”, diethylene glycol dimethyl ether is shown as “D”, diethylene glycol monohexyl ether is shown as “E”, diethylene glycol monobutyl ether acetate is shown as “F”, nonyl alcohol is shown as “G”, triethylene glycol diacetate is shown as “H”, diethylene glycol dibutyl ether is shown as “I”, 1,2-ethane diol is shown as “J”, ethyl octanate is shown as “K”, ethylene glycol monohexyl ether is shown as “L”, diacetone alcohol is shown as “M”, and dimethyl glutarate is shown as “N”.

Further, it is also to be noted that in Table 1 and Table 2 the boiling point of each of the component A and the component B is a boiling point under ordinary pressure (1 atm), the viscosity of each of the component A and the component B is a viscosity measured according to JIS Z8809 using a vibration type viscometer at a temperature of 25° C., the vapor pressure of each of the component A and the component B is a vapor pressure at a temperature of 25° C., and the viscosity of the ink is a viscosity measured according to JIS Z8809 using a vibration type viscometer at a temperature of 25° C.

TABLE 1

| | | Composition of ink for use in color filter | | | | | | | | | | | | |
|---|---|---|---|---|---|---|---|---|---|---|---|---|---|---|
| | | | | | | | | | | Liquid medium | | | | |
| | | | | | | | | | | Component A | | | | |
| | | | | | | Resin | | | | | Boiling | | | |
| | | Coloring agent | | | | material | | Dispersant | | | point | Viscosity | Vapor | Amount |
| | | | Amount | | Amount | | Amount | | Amount | | T_{bp}(a) | η(a) | pressure | X |
| | | | [wt %] | | [wt %] | | [wt %] | | [wt %] | | [° C.] | mPa · s] | [mmHg] | [wt %] |
| Ex. 1 | R ink | PR254 | 5.2 | PY150 | 2 | a | 4.8 | b | 4.7 | A | 213 | 1.7 | 0.14 | 75.0 |
| | G ink | PG36 | 7.0 | PY150 | 2.9 | a | 4.9 | b | 4.9 | A | 213 | 1.7 | 0.14 | 72.3 |
| | B ink | PB15:6 | 4.8 | — | — | a | 4.4 | b | 4.6 | A | 213 | 1.7 | 0.14 | 77.6 |
| Ex. 2 | R ink | PR254 | 5.1 | PY150 | 1.9 | a | 4.9 | b | 4.6 | A | 213 | 1.7 | 0.14 | 50.1 |
| | G ink | PG36 | 6.9 | PY150 | 2.9 | a | 4.9 | b | 4.9 | A | 213 | 1.7 | 0.14 | 48.2 |
| | B ink | PB15:6 | 4.9 | — | — | a | 4.5 | b | 4.3 | A | 213 | 1.7 | 0.14 | 51.8 |
| Ex. 3 | R ink | PR254 | 5.3 | PY150 | 2.1 | a | 4.8 | b | 4.6 | B | 191 | 1.6 | 0.28 | 74.9 |
| | G ink | PG36 | 6.8 | PY150 | 2.9 | a | 4.9 | b | 4.9 | B | 191 | 1.6 | 0.28 | 72.5 |
| | B ink | PB15:6 | 4.8 | — | — | a | 4.3 | b | 4.6 | B | 191 | 1.6 | 0.28 | 77.7 |
| Ex. 4 | R ink | PR254 | 5.1 | PY150 | 2 | a | 4.9 | b | 4.6 | B | 191 | 1.6 | 0.28 | 50.0 |
| | G ink | PG36 | 7.1 | PY150 | 2.9 | a | 4.9 | b | 4.9 | B | 191 | 1.6 | 0.28 | 48.1 |
| | B ink | PB15:6 | 4.9 | — | — | a | 4.5 | b | 4.2 | B | 191 | 1.6 | 0.28 | 51.8 |
| Ex. 5 | R ink | PR254 | 5.0 | PY150 | 2 | a | 4.7 | b | 4.9 | B | 191 | 1.6 | 0.28 | 79.2 |
| | G ink | PG36 | 7.0 | PY150 | 2.9 | a | 4.9 | b | 4.9 | B | 191 | 1.6 | 0.28 | 76.3 |
| | B ink | PB15:6 | 4.8 | — | — | a | 4.4 | b | 4.4 | B | 191 | 1.6 | 0.28 | 82.1 |
| Ex. 6 | R ink | PR254 | 5.2 | PY150 | 1.9 | a | 4.8 | b | 4.7 | C | 171 | 1.2 | 0.45 | 79.2 |
| | G ink | PG36 | 6.9 | PY150 | 2.9 | a | 4.9 | b | 4.9 | C | 171 | 1.2 | 0.45 | 76.4 |
| | B ink | PB15:6 | 4.7 | — | — | a | 4.3 | b | 4.5 | C | 171 | 1.2 | 0.45 | 82.2 |
| Ex. 7 | R ink | PR254 | 5.1 | PY150 | 2.1 | a | 4.7 | b | 4.9 | D | 162 | 1.0 | 0.70 | 79.0 |
| | G ink | PG36 | 6.8 | PY150 | 2.9 | a | 4.9 | b | 4.9 | D | 162 | 1.0 | 0.70 | 81.0 |
| | B ink | PB15:6 | 4.8 | — | — | a | 4.4 | b | 4.5 | D | 162 | 1.0 | 0.70 | 79.2 |
| Ex. 8 | R ink | PR254 | 5.2 | PY150 | 2 | a | 4.8 | b | 4.7 | F | 247 | 3.1 | 0.04 | 82.0 |
| | G ink | PG36 | 5.9 | PY150 | 2.9 | a | 4.9 | b | 4.9 | F | 247 | 3.1 | 0.04 | 79.1 |
| | B ink | PB15:6 | 4.8 | — | — | a | 4.4 | b | 4.4 | F | 247 | 3.1 | 0.04 | 79.1 |

| | | Composition of ink for use in color filter | | | | | | | | |
|---|---|---|---|---|---|---|---|---|---|---|
| | | Liquid medium | | | | | | | | |
| | | Component B | | | | | | | | |
| | | | Boiling | | | | | | | |
| | | | point | Viscosity | Vapor | Amount | | | | Viscosity |
| | | | T_{bp}(b) | η(b) | pressure | Y | | | | of ink η |
| | | | [° C.] | [mPa · s] | [mmHg] | [wt %] | T_{bp}(b) − T_{bp}(a) | η(b) − η(a) | X/Y | [mPa · s] |
| Ex. 1 | R ink | E | 259 | 8.5 | 0.02 | 8.3 | 46 | 6.8 | 9.0 | 7.6 |
| | G ink | E | 259 | 8.5 | 0.02 | 8.0 | 46 | 6.8 | 9.0 | 7.8 |
| | B ink | E | 259 | 8.5 | 0.02 | 8.6 | 46 | 6.8 | 9.0 | 7.4 |
| Ex. 2 | R ink | F | 247 | 3.1 | 0.04 | 33.4 | 34 | 1.4 | 1.5 | 7.6 |
| | G ink | F | 247 | 3.1 | 0.04 | 32.2 | 34 | 1.4 | 1.5 | 7.7 |
| | B ink | F | 247 | 3.1 | 0.04 | 34.5 | 34 | 1.4 | 1.5 | 7.5 |
| Ex. 3 | R ink | E | 259 | 8.5 | 0.02 | 8.3 | 68 | 6.9 | 9.0 | 7.9 |
| | G ink | E | 259 | 8.5 | 0.02 | 8.1 | 68 | 6.9 | 9.0 | 7.9 |
| | B ink | E | 259 | 8.5 | 0.02 | 8.6 | 68 | 6.9 | 9.0 | 7.7 |
| Ex. 4 | R ink | F | 247 | 3.1 | 0.04 | 33.4 | 56 | 1.5 | 1.5 | 7.9 |
| | G ink | F | 247 | 3.1 | 0.04 | 32.1 | 56 | 1.5 | 1.5 | 8.2 |
| | B ink | F | 247 | 3.1 | 0.04 | 34.6 | 56 | 1.5 | 1.5 | 7.9 |
| Ex. 5 | R ink | G | 215 | 14 | 0.13 | 4.2 | 24 | 12.4 | 19 | 8.3 |
| | G ink | G | 215 | 14 | 0.13 | 4.0 | 24 | 12.4 | 19 | 8.2 |
| | B ink | G | 215 | 14 | 0.13 | 4.3 | 24 | 12.4 | 19 | 8.1 |
| Ex. 6 | R ink | G | 215 | 14 | 0.13 | 4.2 | 44 | 12.8 | 19 | 8.0 |
| | G ink | G | 215 | 14 | 0.13 | 4.0 | 44 | 12.8 | 19 | 8.1 |
| | B ink | G | 215 | 14 | 0.13 | 4.3 | 44 | 12.8 | 19 | 7.9 |
| Ex. 7 | R ink | G | 215 | 14 | 0.13 | 4.2 | 53 | 13 | 19 | 7.5 |
| | G ink | G | 215 | 14 | 0.13 | 4.3 | 53 | 13 | 19 | 7.6 |
| | B ink | G | 215 | 14 | 0.13 | 4.2 | 53 | 13 | 19 | 7.3 |
| Ex. 8 | R ink | H | 286 | 9.0 | 0.01 | 4.3 | 39 | 5.9 | 19 | 8.8 |
| | G ink | H | 286 | 9.0 | 0.01 | 4.2 | 39 | 5.9 | 19 | 9.0 |
| | B ink | H | 286 | 9.0 | 0.01 | 4.2 | 39 | 5.9 | 19 | 8.5 |

TABLE 2

| | | Composition of ink for use in color filter | | | | | | | | | | | | |
|---|---|---|---|---|---|---|---|---|---|---|---|---|---|---|
| | | | | | | | | | | Liquid medium | | | | |
| | | | | | | | | | | Component A | | | | |
| | | | | | | Resin | | | | | Boiling | | | |
| | | Coloring agent | | | | material | | Dispersant | | | point | Viscosity | Vapor | Amount |
| | | | Amount | | Amount | | Amount | | Amount | | T_{bp}(a) | η(a) | pressure | X |
| | | | [wt %] | | [wt %] | | [wt %] | | [wt %] | | [° C] | [mPa · s] | [mmHg] | [wt %] |
| Ex. 9 | R ink | PR254 | 5.2 | PY150 | 2 | a | 4.8 | b | 4.7 | C | 171 | 1.2 | 0.45 | 75.0 |
| | G ink | PG36 | 7.0 | PY150 | 2.9 | a | 4.9 | b | 4.9 | C | 171 | 1.2 | 0.45 | 72.3 |
| | B ink | PB15:6 | 4.8 | — | — | a | 4.4 | b | 4.6 | C | 171 | 1.2 | 0.45 | 77.6 |
| Ex. 10 | R ink | PR254 | 5.2 | PY150 | 2 | a | 4.8 | b | 4.7 | C | 171 | 1.2 | 0.45 | 75.0 |
| | G ink | PG36 | 7.0 | PY150 | 2.9 | a | 4.9 | b | 4.9 | C | 171 | 1.2 | 0.45 | 72.3 |
| | B ink | PB15:6 | 4.8 | — | — | a | 4.4 | b | 4.6 | C | 171 | 1.2 | 0.45 | 77.6 |
| Comp. | R ink | PR254 | 5.2 | PY150 | 2 | a | 4.8 | b | 4.7 | B | 191 | 1.6 | 0.28 | 83.3 |
| Ex. 1 | G ink | PG36 | 6.9 | PY150 | 2.9 | a | 4.9 | b | 4.9 | B | 191 | 1.6 | 0.28 | 80.4 |
| | B ink | PB15:6 | 4.8 | — | — | a | 4.4 | b | 4.5 | B | 191 | 1.6 | 0.28 | 85.3 |
| Comp. | R ink | PR254 | 5.2 | PY150 | 2 | a | 4.7 | b | 4.8 | — | — | — | — | — |
| Ex. 2 | G ink | PG36 | 6.9 | PY150 | 2.9 | a | 4.9 | b | 4.8 | — | — | — | — | — |
| | B ink | PB15:6 | 4.8 | — | — | a | 4.6 | b | 4.3 | — | — | — | — | — |
| Comp. | R ink | PR254 | 5.2 | PY150 | 2 | a | 4.7 | b | 4.8 | I | 256 | 1.7 | 0.02 | 75.0 |
| Ex. 3 | G ink | PG36 | 6.9 | PY150 | 2.9 | a | 5.0 | b | 4.8 | I | 256 | 1.7 | 0.02 | 72.4 |
| | B ink | PB15:6 | 4.8 | — | — | a | 4.4 | b | 4.4 | I | 256 | 1.7 | 0.02 | 77.8 |
| Comp. | R ink | PR254 | 5.2 | PY150 | 2 | a | 4.8 | b | 4.8 | K | 208 | 1.4 | 0.16 | 66.6 |
| Ex. 4 | G ink | PG36 | 6.9 | PY150 | 2.9 | a | 4.9 | b | 4.9 | K | 20 | 1.4 | 0.16 | 64.3 |
| | B ink | PB15:6 | 4.8 | — | — | a | 4.4 | b | 4.4 | K | 208 | 1.4 | 0.16 | 69.1 |
| Comp. | R ink | PR254 | 5.2 | PY150 | 2 | a | 4.9 | b | 4.5 | M | 168 | 2.7 | 0.44 | 58.4 |
| Ex. 5 | G ink | PG36 | 6.9 | PY150 | 2.9 | a | 5.0 | b | 4.8 | M | 168 | 2.7 | 0.44 | 56.3 |
| | B ink | PB15:6 | 4.8 | — | — | a | 4.5 | b | 4.3 | M | 168 | 2.7 | 0.44 | 60.5 |

| | | Composition of ink for use in color filter | | | | | | | | |
|---|---|---|---|---|---|---|---|---|---|---|
| | | Liquid medium | | | | | | | | |
| | | Component B | | | | | | | | |
| | | | Boiling | | | | | | | |
| | | | point | Viscosity | Vapor | Amount | | | | Viscosity |
| | | | T_{bp}(b) | η(b) | pressure | Y | | | | of ink η |
| | | | [° C] | [mPa · s] | [mmHg] | [wt %] | T_{bp}(b) − T_{bp}(a) | η(b) − η(a) | X/Y | [mPa · s] |
| Ex. 9 | R ink | E | 259 | 8.5 | 0.02 | 8.3 | 88 | 7.3 | 9.0 | 7.6 |
| | G ink | E | 259 | 8.5 | 0.02 | 8.0 | 88 | 7.3 | 9.0 | 7.8 |
| | B ink | E | 259 | 8.5 | 0.02 | 8.6 | 88 | 7.3 | 9.0 | 7.4 |
| Ex. 10 | R ink | J | 197 | 17.2 | 0.26 | 8.3 | 26 | 16 | 9.0 | 7.6 |
| | G ink | J | 197 | 17.2 | 0.26 | 8.0 | 26 | 16 | 9.0 | 7.8 |
| | B ink | J | 197 | 17.2 | 0.26 | 8.6 | 26 | 16 | 9.0 | 7.4 |
| Comp. | R ink | — | — | — | — | — | — | — | — | 8.0 |
| Ex. 1 | G ink | — | — | — | — | — | — | — | — | 8.1 |
| | B ink | — | — | — | — | — | — | — | — | 7.7 |
| Comp. | R ink | F | 247 | 3.1 | 0.04 | 83.3 | — | — | — | 8.2 |
| Ex. 2 | G ink | F | 247 | 3.1 | 0.04 | 80.5 | — | — | — | 8.3 |
| | B ink | F | 247 | 3.1 | 0.04 | 86.3 | — | — | — | 7.8 |
| Comp. | R ink | J | 197 | 17.2 | 0.26 | 8.3 | −59 | 15.5 | 9.0 | 8.0 |
| Ex. 3 | G ink | J | 197 | 17.2 | 0.26 | 8.0 | −59 | 15.5 | 9.0 | 8.3 |
| | B ink | J | 197 | 17.2 | 0.26 | 8.6 | −59 | 15.5 | 9.0 | 7.8 |
| Comp. | R ink | L | 208 | 4.4 | 0.16 | 16.6 | 0 | 3.0 | 4.0 | 7.6 |
| Ex. 4 | G ink | L | 208 | 4.4 | 0.16 | 16.1 | 0 | 3.0 | 4.0 | 7.7 |
| | B ink | L | 208 | 4.4 | 0.16 | 17.3 | 0 | 3.0 | 4.0 | 7.5 |
| Comp. | R ink | N | 215 | 2.7 | 0.13 | 25.0 | 47 | 0 | 2.3 | 7.9 |
| Ex. 5 | G ink | N | 215 | 2.7 | 0.13 | 24.1 | 47 | 0 | 2.3 | 8.0 |
| | B ink | N | 215 | 2.7 | 0.13 | 25.9 | 47 | 0 | 2.3 | 7.6 |

2 Evaluation of Stability of Droplet Discharge (Evaluation of Discharge Stability)

2.1 Evaluation of Accuracy of Discharged Point

A droplet discharge apparatus as shown in FIG. 3 was placed in a chamber (thermal chamber). Next, three inks (red, green, and blue colors) manufactured in each of the Examples 1 to 10 and the Comparative Examples 1 to 5 were prepared. In a state that a drive waveform of a piezoelectric element of a droplet discharge head provided in the droplet discharge apparatus was optimized, droplets of the three inks were continuously discharged from nozzles of the droplet discharge head onto a substrate. That is to say, 10,000 droplets were discharged onto the substrate under the conditions that a temperature of the inside of the chamber was 23° C. and a range of the temperature thereof was 0.5° C. (23±0.25° C.).

Next, in 10,000 droplets of each of the three inks discharged from predetermined nozzles in the vicinity of the center of the droplet discharge head onto the substrate, differences d between center points of the discharged 10,000 droplets and a center point of an discharging target position were obtained. Thereafter, an average value of the differences d was obtained. The results were evaluated according to the following three criteria A to C. In this regard, it is to be noted that an average value obtained from the average value of the differences d in each of the inks of three colors was used as the average value of the difference d.

A: Average value of the differences d was lower than 0.05 μm.

B: Average value of the differences d was 0.05 μm or higher but lower than 0.10 μm.

C: Average value of the differences d was 0.10 μm or higher.

2.2 Evaluation of Stability of Amount of Discharged Droplet

A droplet discharge apparatus as shown in FIG. 3 was placed in a chamber (thermal chamber). Next, three inks (red, green, and blue colors) manufactured in each of the Examples 1 to 10 and the Comparative Examples 1 to 5 were prepared. In a state that a drive waveform of a piezoelectric element of a droplet discharge head provided in the droplet discharge apparatus was optimized, droplets of the three inks were continuously discharged from nozzles of the droplet discharge head onto a substrate. That is to say, 10,000 droplets were discharged onto the substrate under the conditions that a temperature of the inside of the chamber was 23° C. and a range of the temperature thereof was 0.5° C. (23±0.25° C.).

Next, in each one nozzle of both ends of nozzles other than disable nozzles of the droplet discharge head, a total amount of the droplets (10,000 droplets) discharged therefrom were obtained. Then, an average discharge amount discharged from the one nozzle of one end was calculated by using the total amount thereof and 10,000, that is, a value was obtained by dividing the total amount/10,000. An average discharge amount discharged from the one nozzle of the other end was also calculated by using the total amount thereof and 10,000, that is, a value was obtained by dividing the total amount/10,000.

Thereafter, an absolute value ΔW (ng) of difference between the average discharge amounts was obtained. Then, a ratio (ΔW/W_{T}) between the ΔW and a desired discharge amount W_{T} (ng) of one droplet discharged from each nozzle was obtained. The results were evaluated according to the following three criteria A to C. In this case, if the value of ΔW/W_{T} is small, stability of the amount of the discharged droplet is excellent. In this regard, it is to be noted that an average value obtained from the value of ΔW/W_{T} in each ink of three colors was used as the value of ΔW/W_{T}.

A: Value of ΔW/W_{T} was lower than 0.025.

B: Value of ΔW/W_{T} was 0.025 or higher but lower than 0.625.

C: Value of ΔW/W_{T} was 0.625 or higher.

2.3 Evaluation of Intermittent Printing Performance

A droplet discharge apparatus as shown in FIG. 3 was placed in a chamber (thermal chamber). Next, three inks (red, green, and blue colors) manufactured in each of the Examples 1 to 10 and the Comparative Examples 1 to 5 were prepared. In a state that a drive waveform of a piezoelectric element of a droplet discharge head provided in the droplet discharge apparatus was optimized, droplets of the three inks were continuously discharged from nozzles of the droplet discharge head onto a substrate.

That is to say, 1,000 droplets were discharged onto the substrate. Then, the discharge of the droplets was interrupted for 30 seconds (first sequence). Thereafter, continuous discharge of the droplets and interruption thereof were repeated under the conditions that a temperature of the inside of the chamber was 23° C. and a range of the temperature thereof was 0.5° C. (23±0.25° C.).

Next, in a predetermined nozzle positioned in the vicinity of the center of the droplet discharge head, an average weight W₁ (ng) of the droplets (1,000 droplets) discharged from the nozzle in the first sequence was obtained. An average weight W₁₀ (ng) of the droplets (1,000 droplets) discharged from the nozzle in the tenth sequence was also obtained. Then, an absolute value of difference between W₁ and W₁₀ was obtained.

A ratio (|W₁−W₁₀/W_{T}) between the absolute value and a desired discharge amount W_{T} (ng) of one droplet discharged from each nozzle was obtained. The results were evaluated according to the following three criteria A to C. In this case, if the value of the |W₁−W₁₀|/W_{T} is small, intermittent printing performance (stability of the amount of the discharged droplet) is excellent. In this regard, it is to be noted that an average value obtained from the value of |W₁−W₁₀|/W_{T} in each ink of three colors was used as the value of |W₁−W₁₀|/W_{T}.

A: Value of |W₁−W₁₀|/W_{T} was lower than 0.025.

B: Value of |W₁−W₁₀|/W_{T} was 0.025 or higher but lower than 0.625.

C: Value of |W₁−W₁₀|/W_{T} was 0.625 or higher.

2.4 Continuous Discharge Test

By using a droplet discharge apparatus as shown in FIG. 3 placed in a chamber (thermal chamber) and three inks manufactured in each of the Examples 1 to 10 and the Comparative Examples 1 to 5, the droplet discharge apparatus was continuously operated for 24 hours under a circumstance of 50% RH. That is to say, the three inks constituting an ink set were continuously discharged from the nozzles of a droplet discharge head for 24 hours under the conditions that a humidity of the inside of the chamber was 50% RH, a temperature of the inside of the chamber was 23° C. and a range of the temperature thereof was 0.5° C. (23±0.25° C.).

After continuous operation of the droplet discharge apparatus, an incidence of clogging of the nozzles provided in the droplet discharge head [(number of clogged nozzles)/(number of all nozzles)]×100) was obtained. In the clogged nozzles, it was checked whether removal of the clogging thereof was possible by a cleaning member constituted of a plasticizer material or not. The results were evaluated according to the following four criteria A to D. In this regard, it is to be noted that an average value obtained from the incidence of clogging of the nozzles in each ink of the three colors was used as the value of the incidence thereof.

A: Clogging of the nozzles was not generated.

B: Incidence of the clogging of the nozzles was lower than 0.5% (except for 0) and removal of the clogging was possible by cleaning.

C: Incidence of the clogging of the nozzles was 0.5% or higher but lower than 1.0% and the removal of the clogging was possible by cleaning.

D: Incidence of the clogging of the nozzles was 1.0% or higher or removal of the clogging was impossible by cleaning.

In this regard, it is to be noted that the evaluation described above was carried out under the same conditions in each of the Examples 1 to 10 and the Comparative Examples 1 to 5.

3 Manufacture of Color Filter

A color filter was manufactured by using the inks having red, green and blue colors (ink set) prepared in each of the Examples 1 to 10 and the Comparative Examples 1 to 5, as follows.

First, a substrate (G5 size: 1100×1300 mm) made of a soda glass was prepared, and then silica films (SiO₂) were formed on both surfaces of the substrate. The silica films were provided for preventing sodium ion from eluting from the substrate. Thereafter, the silica films were washed with a predetermined cleaning agent.

Next, a radiosensitive composition containing carbon black for use in forming partitioning walls was supplied on the entire one surface of one of the washed silica films to thereby form a coating film.

Next, the film was subjected to a pre-bake treatment under the conditions that a heating temperature was 110° C. and a heating time was 120 seconds.

Thereafter, radio ray was irradiated to the film through a photo-mask for irradiating a part of the film corresponding to the partitioning walls. Then, the irradiated film was subjected to a post-exposure bake treatment (PEB), and then was subjected to a development treatment using an alkaline developer to obtain partitioning walls. The partitioning walls and the substrate were further subjected to a post-bake treatment.

In this regard, it is to be noted that the PEB was carried out under the conditions that a heating temperature was 110° C., a heating time was 120 seconds and irradiation intensity of the radio ray was 150 mJ/cm². Further, it is also to be noted that the development treatment was carried out by using a vibration dipping method under the conditions that a development treatment time was 60 seconds. Furthermore, the post-bake treatment was carried out under the conditions that a heating temperature was 150° C. and a heating time was 5 minutes. A thickness of the thus obtained partitioning walls was 2.1 μm.

Next, by using a droplet discharge apparatus as shown in FIG. 3 placed in a chamber (thermal chamber), the manufactured three inks were discharged into cells which were surrounded by the partitioning walls. At this time, the three inks of three colors (green, red and blue) were discharged so that the three inks were not mixed to each other. In this regard, it is to be noted that a temperature of the inside of the chamber was set to 23° C. and a range of the temperature thereof was set to 0.5° C. (23±0.25° C.).

Thereafter, the discharged three inks were subjected to a heating treatment on a hot plate for 10 minutes at 100° C., and further subjected to the heating treatment in an oven for 1 hour at 200° C. together with the substrate and the partitioning walls to obtain coloring parts for the three colors. As a result, the color filter as shown in FIG. 1 was manufactured.

By using the three inks (ink set) obtained in each of the Examples 1 to 10 and the Comparative Examples 1 to 5, 1,000 color filters were manufactured in the same method (steps) as that described above.

4 Evaluation

The following evaluations were carried out using each color filter obtained as described above.

4.1 Uneven Color, Uneven Density and Light Leakage

A liquid crystal display apparatus as shown in FIG. 7 was produced by using the 1,000^{th} color filter in the 1,000 color filters manufactured by using the three inks (ink set) obtained in each of the Examples 1 to 10 and the Comparative Examples 1 to 5.

Each of red monochrome image, green monochrome image, blue monochrome image and white monochrome image was displayed in a dark room by using the liquid crystal display apparatus. Each of the red monochrome image, green monochrome image, blue monochrome image and white monochrome image was visually observed. The results, that is, uneven color, uneven density and light leakage in various portions of the 1,000^{th} color filter were evaluated according to the following five criteria A to E.

A: Uneven color, uneven density and light leakage were not observed at all.

B: Uneven color, uneven density and light leakage were scarcely observed.

C: Uneven color, uneven density and light leakage were slightly observed.

D: Uneven color, uneven density and light leakage were clearly observed.

E: Uneven color, uneven density and light leakage were conspicuously observed.

In this regard, it is to be noted that the evaluation described above was carried out in the same manner in each of the liquid crystal display apparatuses manufactured by using the three inks obtained in each the Examples 1 to 10 and the Comparative Examples 1 to 5.

4.2 Characteristics Difference among Color Filters

990^{th} to 999^{th} color filters in the 1,000 color filters manufactured by using the three inks (ink set) obtained in each of the Examples 1 to 10 and the Comparative Examples 1 to 5 were prepared. Then, ten liquid crystal display apparatuses as shown in FIG. 7 were produced by using the 990^{th} to 999^{th} color filters.

Then each of red monochrome image, green monochrome image, blue monochrome image and white monochrome image was displayed in a dark room by using the ten liquid crystal displaying apparatuses. Thereafter, each of the displayed images was subjected to a spectrophotometer (“MCPD3000” produced by Otsuka Electronics Co., Ltd.) to measure reflectance or transmittance of light having a wavelength of each color in each color filter.

In each of the four color images displayed by the ten liquid crystal display apparatuses, ten points were obtained by using the reflectance or the transmittance of the light in a “Lab” color coordinate system. Then, a difference between a maximum point and a minimum point in the ten points was obtained in each of the four color images. That is to say, a color difference (ΔE) was obtained in each of the four color images.

Thereafter, the largest color difference (ΔE) in the color differences (AEs) of the four color images (red, green, blue and white) was evaluated according to the following five criteria A to E.

A: Color difference (ABE) was smaller than 2.

B: Color difference (ΔE) was 2 or larger but smaller than 3.

C: Color difference (ΔE) was 3 or larger but smaller than 4.

D: Color difference (ΔE) was 4 or larger but smaller than 5.

E: Color difference (ΔE) was 5 or larger.

In this regard, it is to be noted that the evaluation described above was carried out in the same manner in each of the liquid crystal display apparatuses manufactured by using the three inks obtained in each of the Examples 1 to 10 and the Comparative Examples 1 to 5.

4.3 Durability

A liquid crystal display apparatus as shown in FIG. 7 was produced by using the 1,000^{th} color filter in the 1,000 color filters manufactured by using the three inks (ink set) obtained in each of the Examples 1 to 10 and the Comparative Examples 1 to 5.

Each of the liquid crystal display apparatuses was placed for 200 hours under the conditions that a temperature was 60° C. and a relative humidity was 80% RH. Thereafter, images were displayed by the liquid crystal display apparatuses. It was evaluated according to the following three criteria A to C whether the images were appropriately displayed by the liquid crystal display apparatuses or not.

A: Images were displayed appropriately and the displayed images were clear.

B: Images were displayed appropriately but the displayed images were slightly unclear.

C: Images were not displayed appropriately.

In this regard, it is to be noted that the evaluation described above was carried out in the same manner in each of the liquid crystal display apparatuses manufactured by using the three inks obtained in each of the Examples 1 to 10 and the Comparative Examples 1 to 5.

These results are shown in Table 3.

TABLE 3

| | Evaluation of discharge stability | | | | Evaluation of color filter | | |
|---|---|---|---|---|---|---|---|
| | Accuracy | Stability | | | Uneven color, | Characteristics | |
| | of | of amount | Intermittent | Continuous | uneven density | difference | |
| | discharged | of discharged | printing | discharge | and | among | |
| | point | droplet | performance | test | light leakage | color filters | Durability |
| Ex. 1 | A | A | A | A | A | A | A |
| Ex. 2 | B | A | A | A | A | A | A |
| Ex. 3 | B | A | A | A | A | A | A |
| Ex. 4 | A | A | B | A | A | A | A |
| Ex. 5 | B | B | B | A | A | A | A |
| Ex. 6 | B | B | B | A | A | A | A |
| Ex. 7 | A | B | B | C | A | A | B |
| Ex. 8 | B | A | A | A | A | A | A |
| Ex. 9 | B | A | C | A | B | A | A |
| Ex. 10 | B | A | A | A | B | C | A |
| Comp. | B | B | C | A | D | C | B |
| Ex. 1 | | | | | | | |
| Comp. | A | A | A | C | C | C | A |
| Ex. 2 | | | | | | | |
| Comp. | B | A | B | B | D | C | B |
| Ex. 3 | | | | | | | |
| Comp. | A | A | B | C | D | D | B |
| Ex. 4 | | | | | | | |
| Comp. | B | A | C | D | E | E | C |
| Ex. 5 | | | | | | | |

As shown in the Table 3, the color filter according to the present invention (that is, the color filters manufactured by using the three inks of the Examples 1 to 10) did not have mixing color, uneven color and uneven density. Further, the color filter according to the present invention also prevented light leakage from generating. Furthermore, characteristics among the color filters also had small variations. In contrast, in the color filters of the Comparative Examples 1 to 5, satisfactory results could not be obtained.

A commercially available television was disassembled, then a liquid crystal displaying apparatus thereof was changed to the liquid crystal displaying apparatus of the present invention manufactured as described above to obtain a liquid crystal television (electronic apparatus). In this way, liquid crystal televisions corresponding to the Examples 1 to 10 and the Comparative Examples 1 to 5 were prepared. Thereafter, the liquid crystal televisions were evaluated in the same manner as described above. The results were obtained in the same as those described above.

What is claimed is:

1. An ink for use in manufacturing a color filter by an ink-jet together with other inks, the ink having a predetermined color which is different from colors of the other inks, the ink comprising:
a coloring agent which has a color corresponding to the predetermined color of the ink; and
a liquid medium in which the coloring agent is dissolved and/or dispersed, the liquid medium comprised of a component A and a component B;
wherein a boiling point of the component B is higher than a boiling point of the component A, and a viscosity of the component B at a temperature of 25° C. is higher than a viscosity of the component A at a temperature of 25° C.

2. The ink as claimed in claim 1, wherein when the boiling point of the component A under an atmospheric pressure is defined as T_{bp}(a) [° C.] and the boiling point of the component B under the atmospheric pressure is defined as T_{bp}(b) [° C.], T_{bp}(a) and T_{bp}(b) satisfy a relation: 20≦T_{bp}(b)−T_{bp}(a)≦70.

3. The ink as claimed in claim 1, wherein when the viscosity of the component A at a temperature of 25° C. is defined as η(a) [mPa·s] and the viscosity of the component B at a temperature of 25° C. is defined as η(b) [mPa·s], η(a) and η(b) satisfy a relation: 1≦η(b)−η(a)≦15.

4. The ink as claimed in claim 1, wherein when an amount of the component A in the ink is defined as X [wt %] and an amount of the component B in the ink is defined as Y [wt %], X and Y satisfy a relation: 1.0≦X/Y≦20.

5. The ink as claimed in claim 1, wherein the other inks contain the liquid medium, and the liquid medium contained in each of the ink and the other inks includes as the component A any one or more selected from the group comprising diethylene glycol dimethyl ether, diacetone alcohol, 3-methoxy n-butyl acetate, dipropylene glycol dimethyl ether, 3-ethoxy ethyl propionate, diethylene glycol ethyl methyl ether, diethylene glycol diethyl ether, ethyl octanoate, ethylene glycol monobutyl ether acetate, ethylene glycol monobutyl ether, cyclohexyl acetate, 1,3-butylene glycol diacetate, ethylene glycol butyl methyl ether, ethylene glycol hexyl methyl ether, ethylene glycol dibutyl ether, and 2-(2-methoxy-1-methylethoxy)-1-methyl ethyl acetate.

6. The ink as claimed in claim 1, wherein the other inks contain the liquid medium, and the liquid medium contained in each of the ink and the other inks includes as the component B any one or more selected from the group comprising tripropylene glycol methyl ether, triethylene glycol monomethyl ether, 4-methyl-1,3-dioxolane-2-on, diethylene glycol monobutyl ether, diethylene glycol monobutyl ether acetate, bis(2-buthoxyethyl)ether, 1,3-butylene glycol diacetate, triethylene glycol diacetate, ethylene glycol monobutyl ether acetate, triethylene glycol butyl methyl ether, nonyl alcohol, triacetine, propylene glycol phenyl ether, and diethylene glycol monohexyl ether.

7. The ink as claimed in claim 1, wherein a viscosity of the ink at the temperature of 25° C. is in the range of 5 to 12 mPa·s.

8. The ink as claimed in claim 1, wherein the predetermined color of the ink includes a red color, a green color and a blue color.

9. A color filter manufactured using the ink defined in claim 1.

10. A method of manufacturing a color filter, the method comprising:
preparing a substrate having a large number of cells to which a plurality of inks having different colors are to be discharged;
discharging the plurality of inks into the cells by an ink-jet; and
drying the plurality of inks which are discharged into the cells by the ink-jet;
wherein each of the plurality of inks comprises a coloring agent which has a predetermined color corresponding to the color of one ink in the plurality of inks and a liquid medium in which the coloring agent is dissolved and/or dispersed, and the liquid medium comprised of a component A and a component B, wherein a boiling point of the component B is higher than a boiling point of the component A, and a viscosity of the component B at a temperature of 25° C. is higher than a viscosity of the component A at a temperature of 25° C.

11. An image display apparatus provided with the color filter defined in the claim 9.

12. The image display apparatus claimed in claim 11, wherein the image display apparatus is a liquid crystal panel.

13. An electronic apparatus provided with the image display apparatus defined in claim 11.
